(19) United States
(12) Patent Application Publication
(10) Pub. No.: US 2026/0239879 A1
(43) Pub. Date: Aug. 13, 2026

(54) BORON-NITROGEN COMPOUND WITH MULTI-MEMBERED FUSED RING, ORGANIC ELECTROLUMINESCENT DEVICE, COMPOSITION AND PREPARATION CONTAINING SAME, AND DISPLAY APPARATUS

(71) Applicant: YURUI (SHANGHAI) CHEMISTRY CO., LTD., Shanghai (CN)

(72) Inventors: Lei ZHANG, Shanghai (CN); Yunqi LIU, Shanghai (CN); Huaxing ZHANG, Shanghai (CN); Kongwu WU, Shanghai (CN); Xiaoyu ZHAO, Shanghai (CN)

(21) Appl. No.: 19/171,638

(22) Filed: Apr. 7, 2025

(30) Foreign Application Priority Data
Feb. 11, 2025 (CN) 202510147862.5

(51) Int. Cl. H10K 85/60; C07B 59/00; C07F 5/02; C07F 7/08; C09K 11/06; H10K 50/12; H10K 85/40

(52) U.S. Cl. CPC H10K 85/658; C07B 59/004; C07F 5/027; C07F 7/0812; C07F 7/0816; C09K 11/06; H10K 85/40; H10K 85/615; H10K 85/622; H10K 85/623; H10K 85/626; H10K 85/6572; H10K 85/6574; H10K 85/6576; C07B 2200/05; C09K 2211/1007; C09K 2211/1011; C09K 2211/1018; H10K 50/12

(57) ABSTRACT

A boron-nitrogen compound with a multi-membered fused ring, and an OLED containing the same, and an organic light-emitting apparatus are provided. By the cooperation of a fused heterocyclic structure with limiting groups such as a tert-butyl group and a cycloalkyl group, the boron-nitrogen compound may improve the thermal stability of the compound and have excellent light-emitting characteristics. By using the boron-nitrogen compound as a light-emitting layer material, it may be possible to effectively enable an organic light-emitting device to have a low driving voltage, maintain the voltage stability and have an improved light-emitting efficiency.

### CROSS-REFERENCE TO RELATED APPLICATION

This application claims priority to Chinese Patent Application No. 202510147862.5, filed on Feb. 11, 2025, titled “BORON-NITROGEN COMPOUND WITH MULTI-MEMBERED FUSED RING, OLED CONTAINING SAME, AND ORGANIC LIGHT-EMITTING APPARATUS”, which is incorporated herein by reference in its entirety.

### TECHNICAL FIELD

The present disclosure relates to the technical field of organic optoelectronic material preparation, in particular, to a boron-nitrogen compound with a multi-membered fused ring, and an organic electroluminescent device, a composition and a preparation containing the same, and a display apparatus.

### BACKGROUND

An organic electroluminescent diode (also referred to as an organic light-emitting diode, abbreviated as an OLED), also referred to as an organic electroluminescent device, relates to a technology that a voltage is applied on an organic electroluminescent element to inject holes from an anode into a light-emitting layer and inject electrons from a cathode into the light-emitting layer so as to enable the injected holes and electrons to combine to form excitons for light emission. The organic electroluminescent diode is capable of converting electrical energy into light energy by means of an organic light-emitting material.

Light-emitting layers of OLED devices mostly adopt a host-guest light-emitting system, i.e., a system of doping a host material with a guest material. At present, green light dopant materials are studied mostly with boron-nitride hetero-fused ring molecules as hotspots. However, the types and number of existing materials are still relatively small, resulting difficulty in the study of the structure-activity relationship. In addition, despite the application of the boron-nitride hetero-fused ring molecules, display technologies still suffer from problems such as high driving voltage and short display lifespan, which seriously affects the further practicality of the technologies.

Therefore, continuous efforts are needed to develop organic light-emitting devices with low driving voltage, high brightness and long lifespan. It is a long-term need in this field to find suitable OLED photoelectric functional materials for OLED devices in order to solve the above problems.

### SUMMARY

In order to solve the above technical problems, the present disclosure provides a boron-nitrogen compound with a multi-membered fused ring, and an OLED containing the same, and a display or lighting apparatus. The boron-nitrogen compound may improve the light-emitting efficiency and thermal stability by means of cooperation of a boron-nitrogen fused heterocycle with limiting groups, a molecular structure of the boron-nitrogen compound is readily modified. By using the boron-nitrogen compound provided in the present disclosure as a light-emitting layer material, it may be possible to effectively enable an organic light-emitting device to have a low driving voltage, maintain the voltage stability and have an improved light-emitting efficiency.

The boron-nitrogen compound with the multi-membered fused ring provided in the present disclosure is realized by means of following technical solutions.

The boron-nitrogen compound with the multi-membered fused ring has a structure as shown in following formula I:

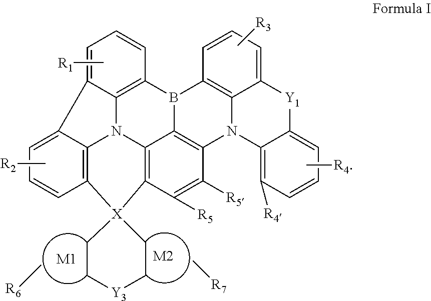

In formula I, X is selected from C and Si; Y₁ and Y₃ each represent absence or presence; in a case where Y₁ and/or Y₃ represent presence, Y₁ and Y₃ are each independently selected from a single bond, O, S, C(CH₃)₂ and Si(CH₃)₂; and a ring M1 and a ring M2 each independently represent one or more of a C3-C20 cycloalkyl group, a C6-C30 aromatic ring and a C5-C36 heteroaromatic ring;
R₁-R₄, R₆ and R₇ each represent non-substitution, mono-substitution or multi-substitution;
R₁-R₄ each, identically or differently, represent one group or a plurality of groups selected from of hydrogen, deuterium, a C1-C20 alkyl group, a substituted or unsubstituted C3-C20 cycloalkyl group and a substituted or unsubstituted C6-C30 aryl group;
R₄′ is selected from of hydrogen, deuterium, a C1-C20 alkyl group, a substituted or unsubstituted C3-C20 cycloalkyl group and a substituted or unsubstituted C6-C30 aryl group;
R₅ is selected from hydrogen and deuterium, and R₅′ represents one or more independently selected from of deuterium, a substituted C6-C30 aryl group, a substituted or unsubstituted C5-C36 heteroaryl group and a C6-C36 aryl silane group; or R₅ is selected from deuterium, a C1-C20 alkyl group and a C6-C30 aryl group, and R₅′ is bonded to R₄′ to form a ring; or R₅ and R₅′ are each deuterium;
R₆ and R₇ are each, identically or differently, selected from hydrogen, deuterium, a C1-C20 alkyl group, a C1-C20 alkylamine group and C6-C36 arylamine group; and
in a case where any one of R₁-R₄, R₄′ and R₅′ contains a substituent, the substituent is independently selected from hydrogen, deuterium, a C1-C20 alkyl group, a C3-C20 cycloalkyl group and a C6-C18 aryl group.

A hydrogen atom in the compound shown in formula I of the present disclosure may be substituted by deuterium, tritium, a cyano group or a halogen atom.

In some embodiments, any one of R₁-R₄ represents a plurality of groups selected from of hydrogen, deuterium, a C1-C20 alkyl group, a substituted or unsubstituted C3-C20 cycloalkyl group and a substituted or unsubstituted C6-C30 aryl group; and any two adjacent groups among the plurality of groups form a saturated or unsaturated C3-C12 membered ring.

In some embodiments, the structure of the boron-nitrogen compound with the multi-membered fused ring is as shown in following formula II:

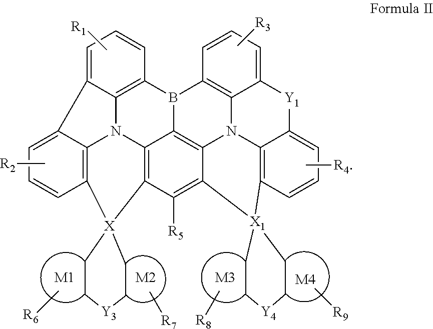

In formula II, X and X1 are selected from C and Si; Y₃ represents presence, and is selected from a single bond, O, S, C(CH₃)₂ and Si(CH₃)₂; Y₄ is selected from a single bond, O and S; the ring M1, the ring M2, a ring M3 and a ring M4 each independently represent one or more of a C6-C30 aromatic ring and a C3-C20 cycloalkyl group; and in a case where X and X1 are each Si, at least one of the ring M1, the ring M2, the ring M3 and the ring M4 is a C3-C20 cycloalkyl fused substituted C6-C30 aromatic ring;
R₁, R₂, R₃ and R₄ each represent non-substitution, mono-substitution or multi-substitution;
R₁, R₂, R₃ and R₄ are each, identically or differently, one group or a plurality of groups selected from hydrogen, deuterium, a C1-C20 alkyl group, a C1-C20 alkyl-substituted C3-C20 cycloalkyl group and an unsubstituted C3-C20 cycloalkyl group;
R₅ is selected from hydrogen, deuterium, a C1-C20 alkyl group and a C6-C30 aryl group;
R₆ and R₇ are each, identically or differently, selected from hydrogen, deuterium, a C1-C20 alkyl group, a C1-C20 alkylamine group and a C6-C36 arylamine group; and R₈ and R₉ are each, identically or differently, one or more selected from hydrogen, deuterium and a C1-C20 alkyl group.

In some embodiments, any one of R₁-R₄ represents a plurality of groups selected from hydrogen, deuterium, a C1-C20 alkyl group, a C1-C20 alkyl-substituted C3-C20 cycloalkyl group and an unsubstituted C3-C20 cycloalkyl group; and any two adjacent groups among the plurality of groups form a saturated or unsaturated C3-C12 membered ring.

In some embodiments, the ring M1, the ring M2, the ring M3 and the ring M4 in formula I or formula II each independently represent a phenyl group, a naphthyl group and a tetrahydronaphthyl group.

In some embodiments, R₁, R₂, R₃ and R₄ in formula I or formula II are each, identically or differently, selected from hydrogen, deuterium, a methyl group, an ethyl group, a propyl group, a butyl group, a pentyl group, a hexyl group, a heptyl group, an adamantyl group, a methyl-substituted fused cyclopentyl group, a methyl-substituted fused cyclohexane group, a tert-butyl-substituted phenyl group, and an unsubstituted phenyl group.

In some embodiments, in formula I, R₅ is selected from hydrogen and deuterium, and R₅′ is one or more independently selected from deuterium, a deuterated phenyl group, a tert-butylphenyl group, a terphenyl group, a triphenylsilyl group, a tetraphenylsilyl group, a biphenyl group, a tert-butyl-substituted biphenyl group, a carbazolyl group and an N-phenylcarbazolyl group.

In some embodiments, R₆ and R₇ are each independently selected from hydrogen, deuterium, a methyl group, an ethyl group, a propyl group, a tert-butyl group, a dimethylamine group and a diphenylamino group.

In some embodiments, the structure defined in formula I is selected from any one of structures as shown in following formula I-1 and formula I-2:

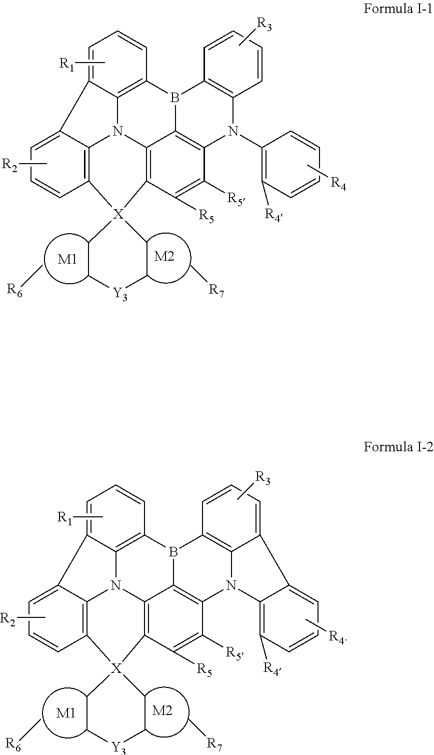

In formula I-1 and formula I-2, substitution ranges of the ring M1, the ring M2, X, Y₃, R₁, R₂, R₃, R₄, R₅, R₆, R₇, R₄′, R₅′ are same as that defined in formula I.

In one or more embodiments, the structure of the boron-nitrogen compound with the multi-membered fused ring is any one selected from following chemical structures:

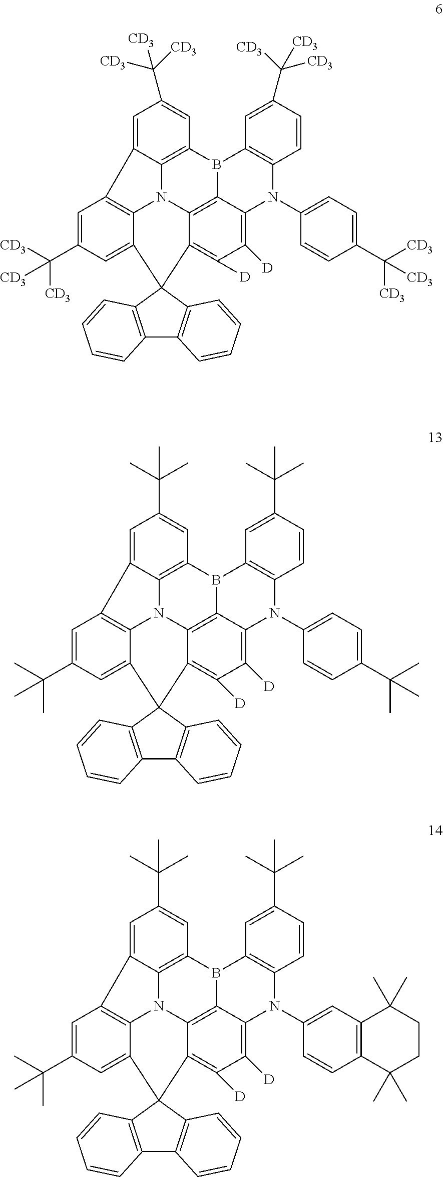

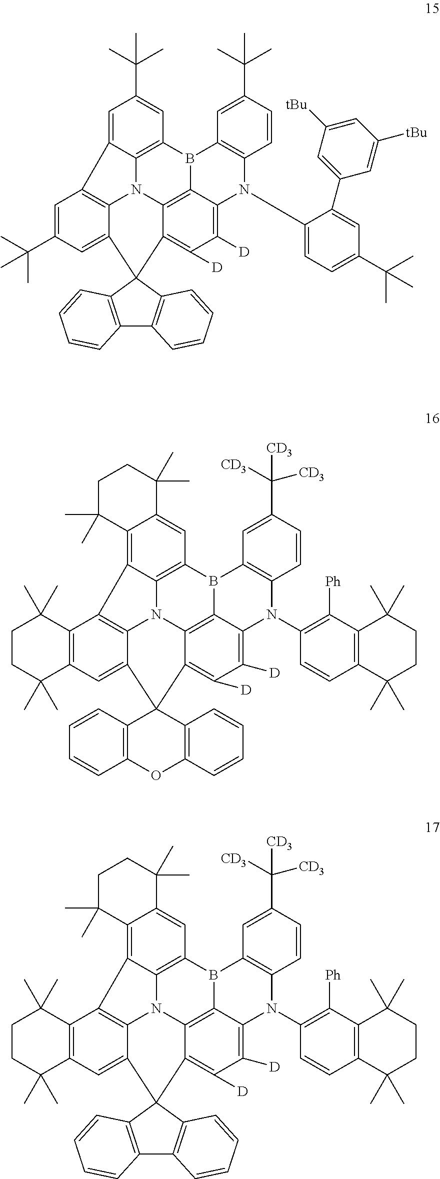

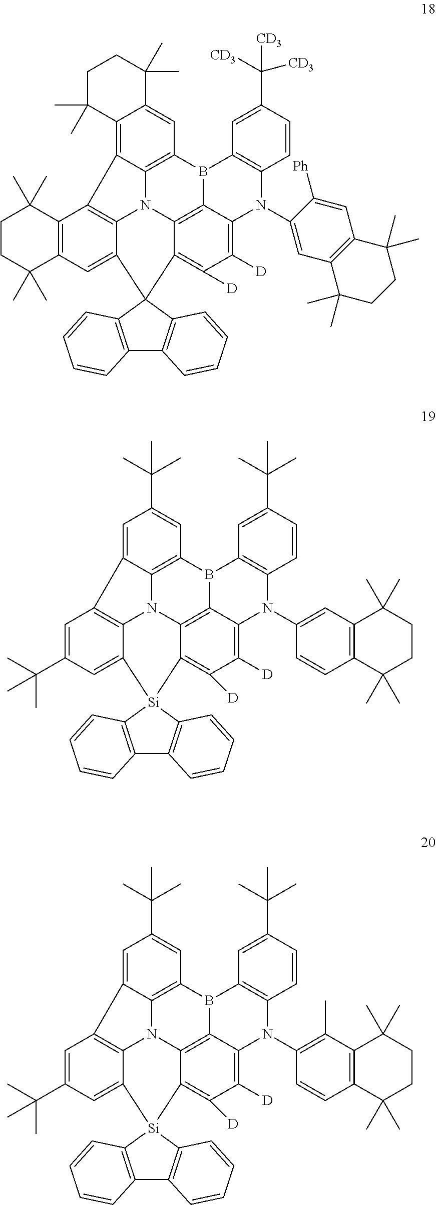

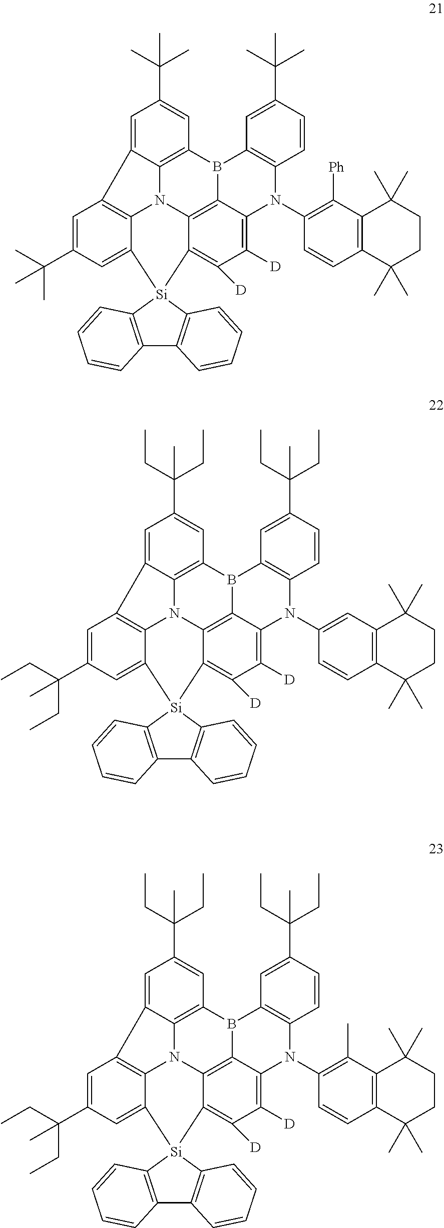 [SMILES: [2H]c1c([2H])c2c3c4c1N(c1ccc5c(c1-c1ccccc1)C(C)(C)CCC5(C)C)c1ccc(C(C)(C)C)cc1B4c1cc(C(C)(C)C)cc4c5cc(C(C)(C)C)cc(c5n-3c14)[Si]21c2ccccc2-c2ccccc21 ; [2H]c1c([2H])c2c3c4c1N(c1ccc5c(c1)C(C)(C)CCC5(C)C)c1ccc(C(C)(CC)CC)cc1B4c1cc(C(C)(CC)CC)cc4c5cc(C(C)(CC)CC)cc(c5n-3c14)[Si]21c2ccccc2-c2ccccc21 ; [2H]c1c([2H])c2c3c4c1N(c1ccc5c(c1C)C(C)(C)CCC5(C)C)c1ccc(C(C)(CC)CC)cc1B4c1cc(C(C)(CC)CC)cc4c5cc(C(C)(CC)CC)cc(c5n-3c14)[Si]21c2ccccc2-c2ccccc21]

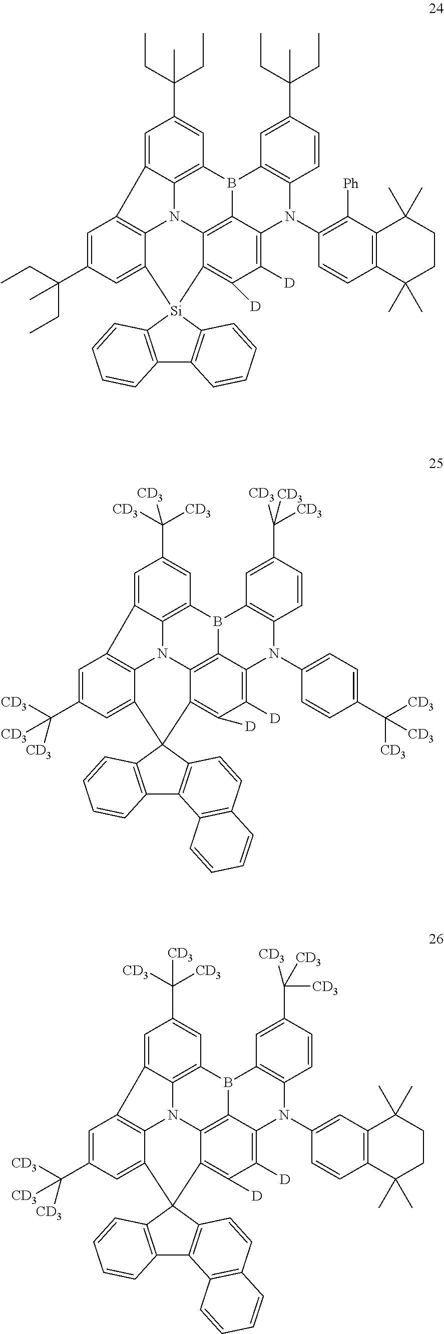

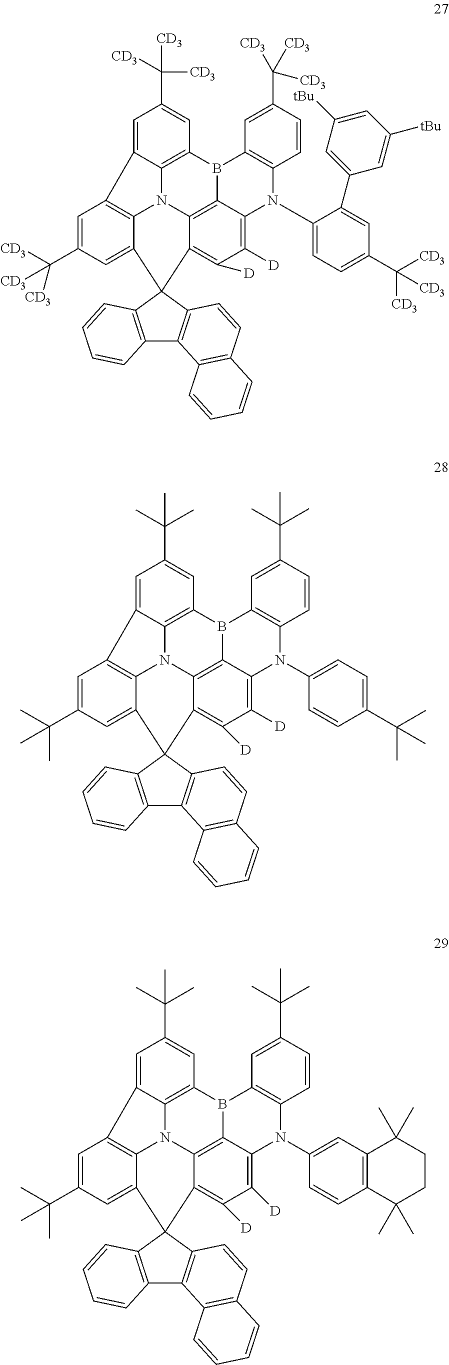

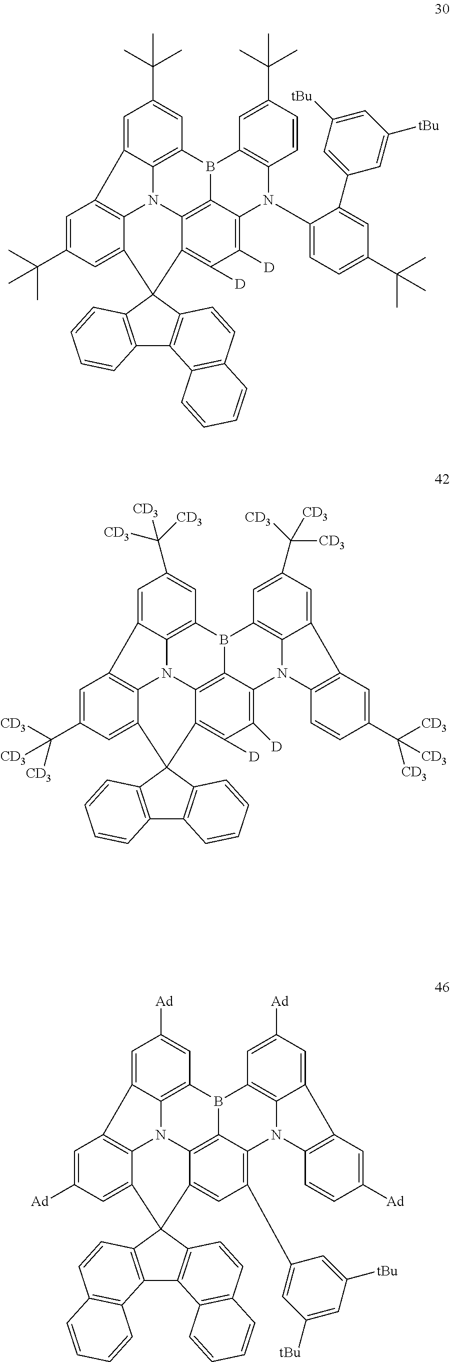

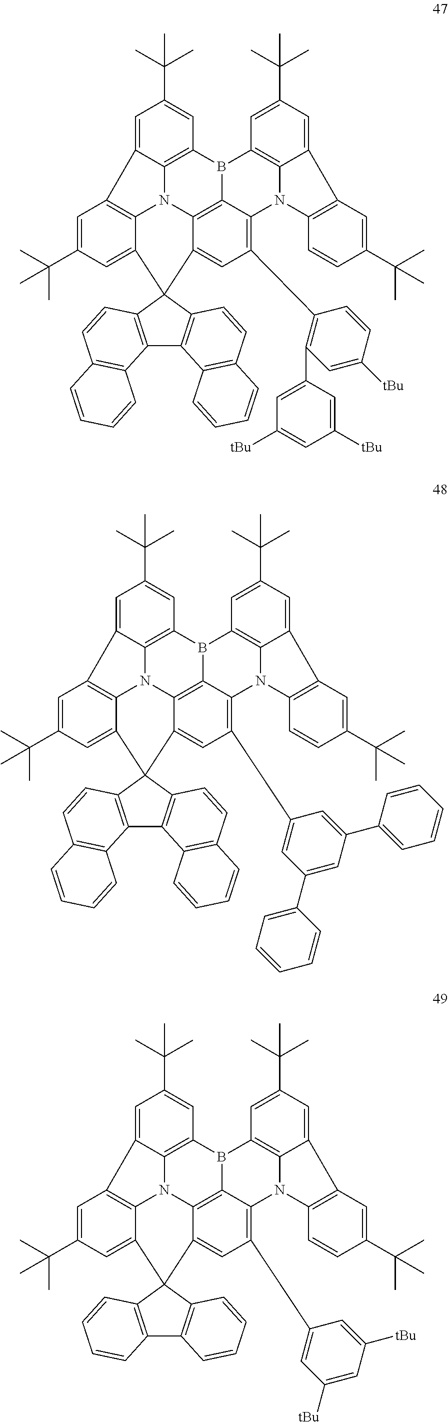

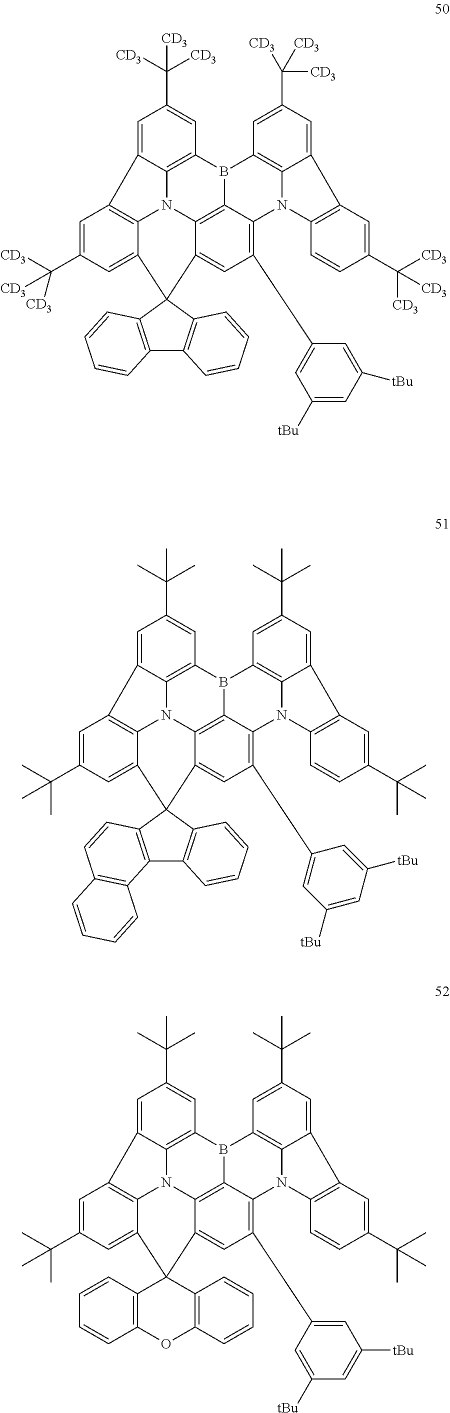

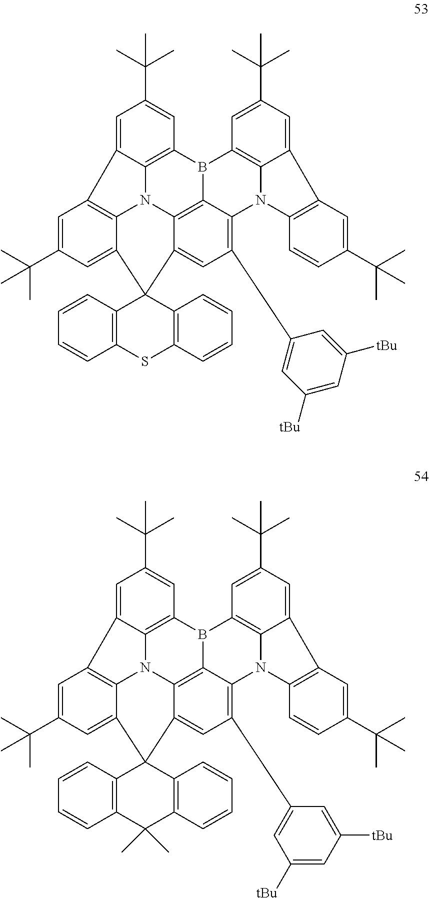

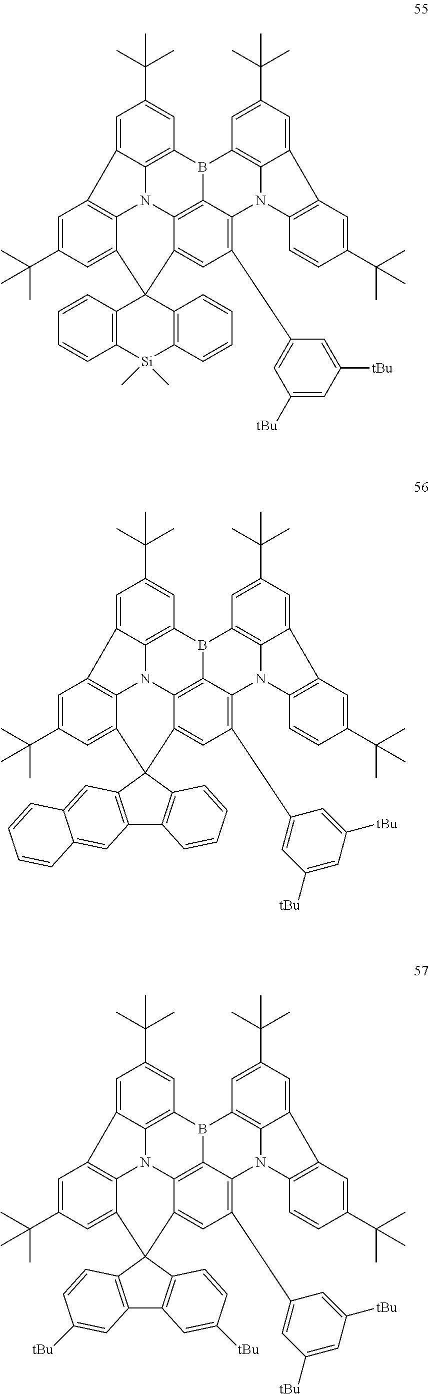

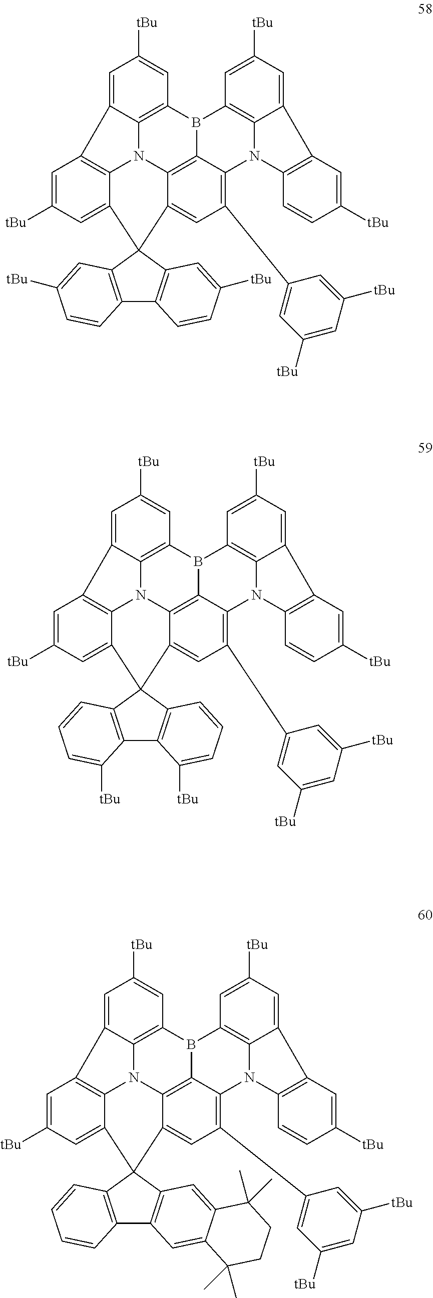

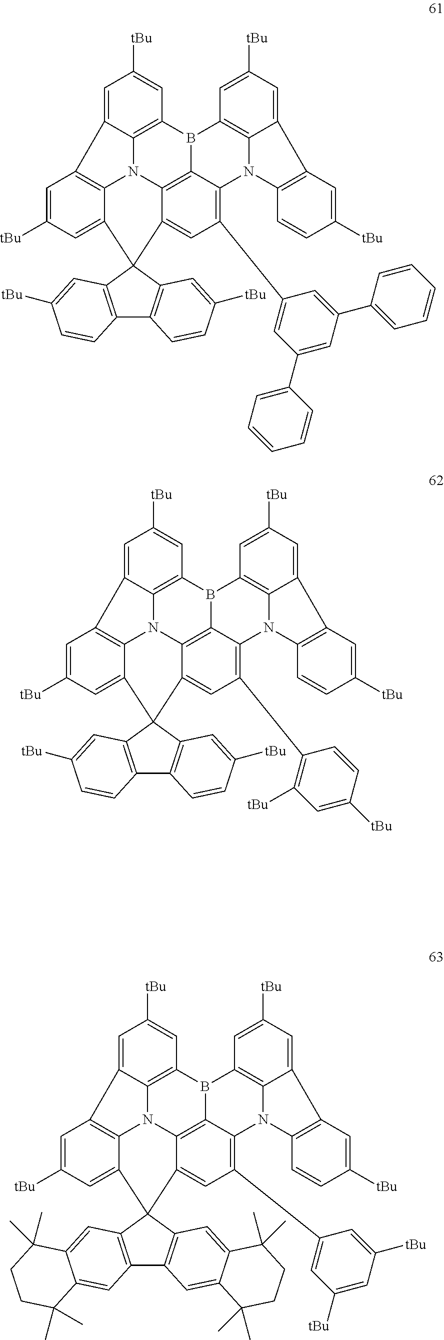

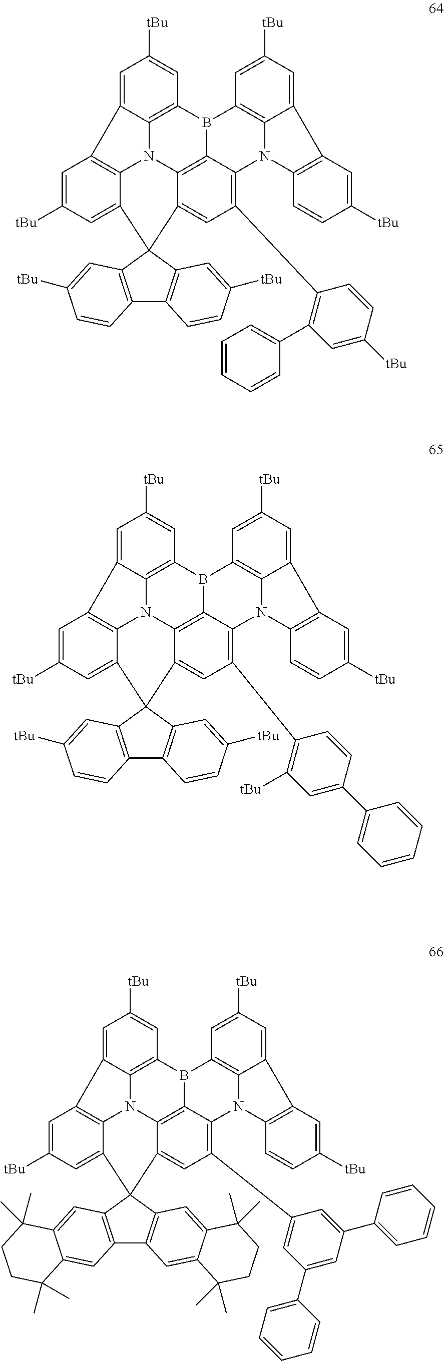

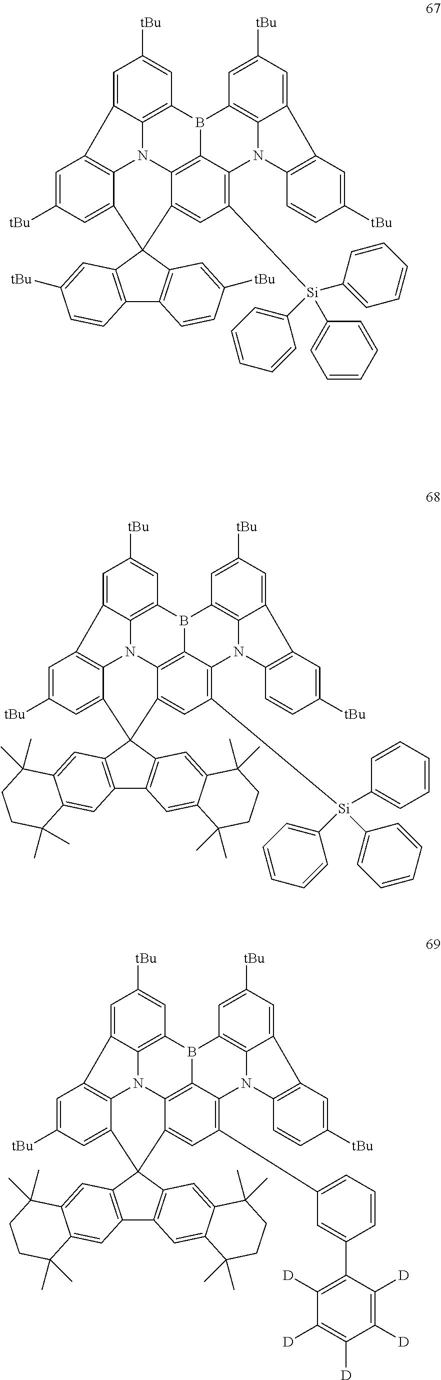

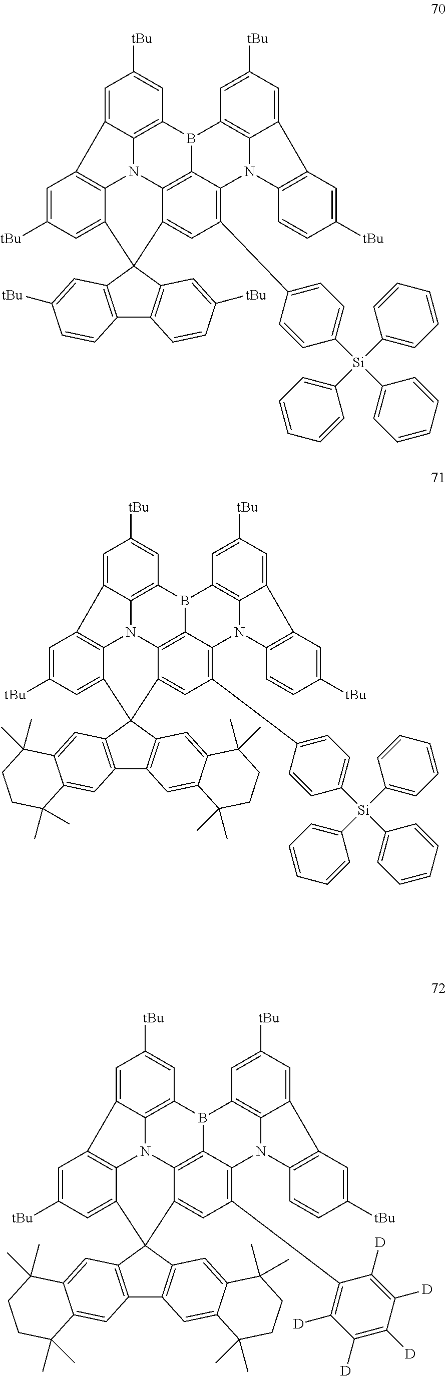

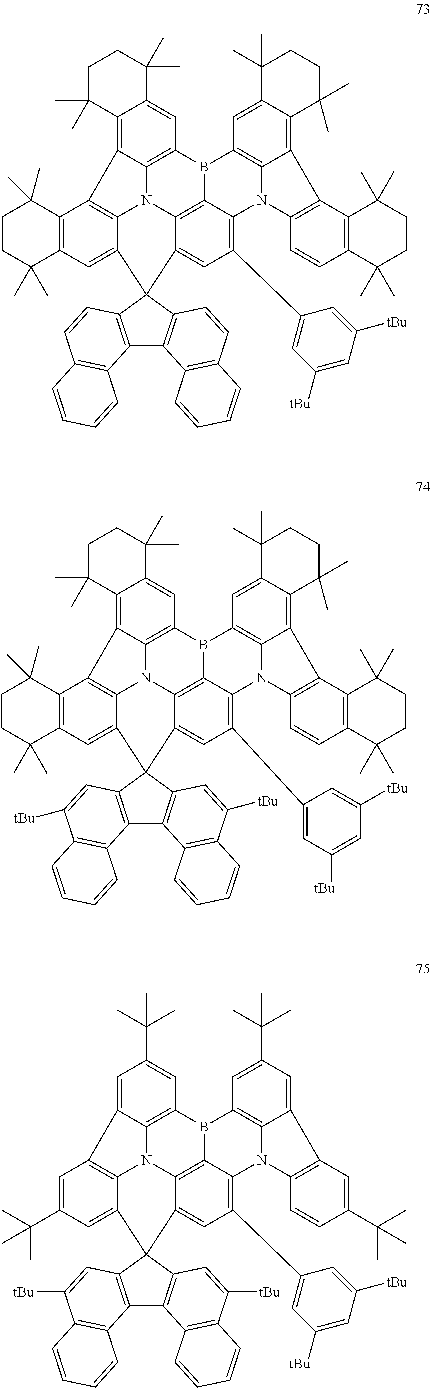

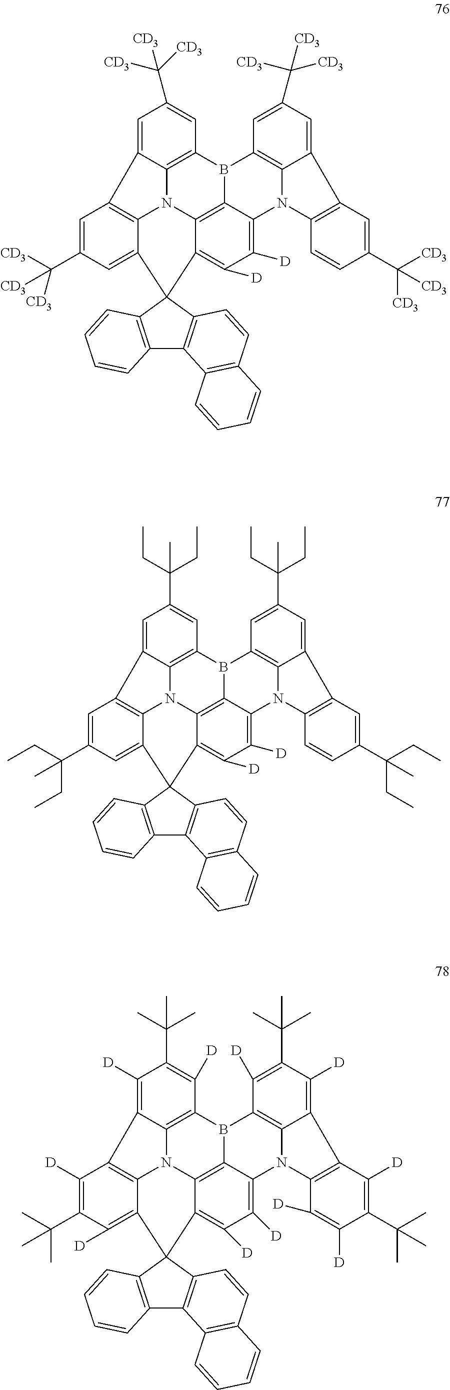

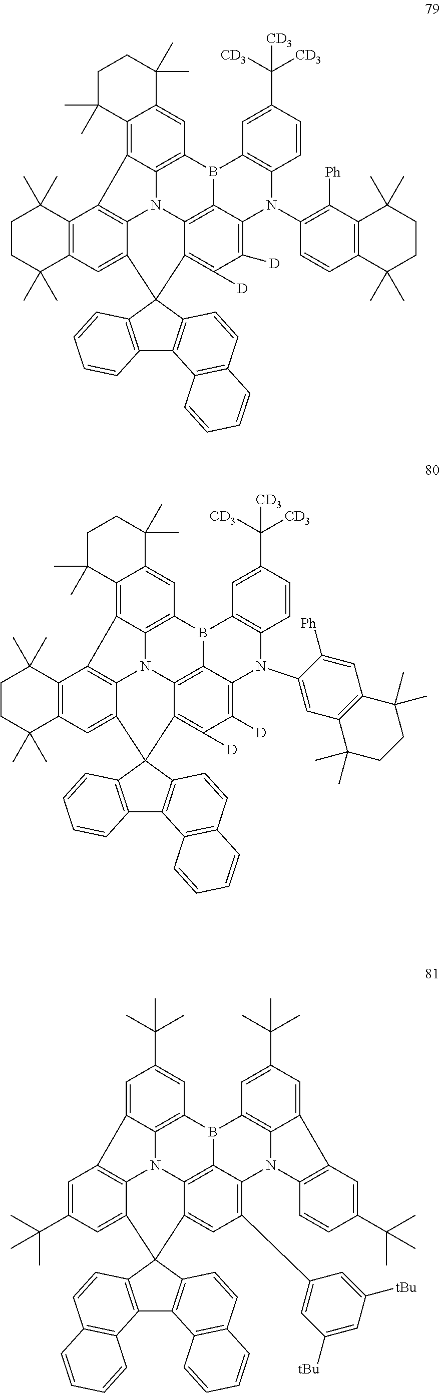

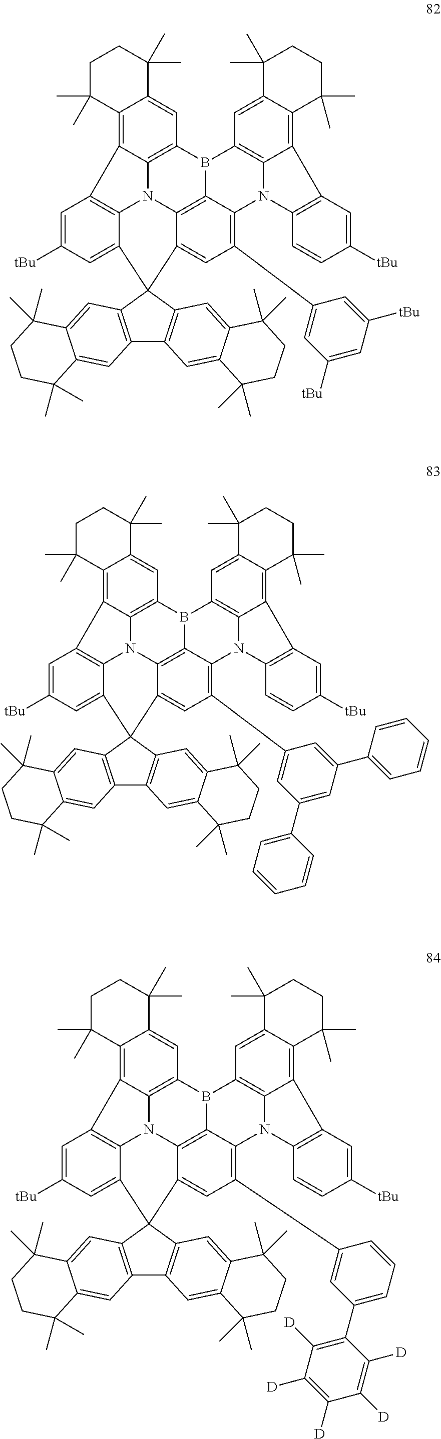

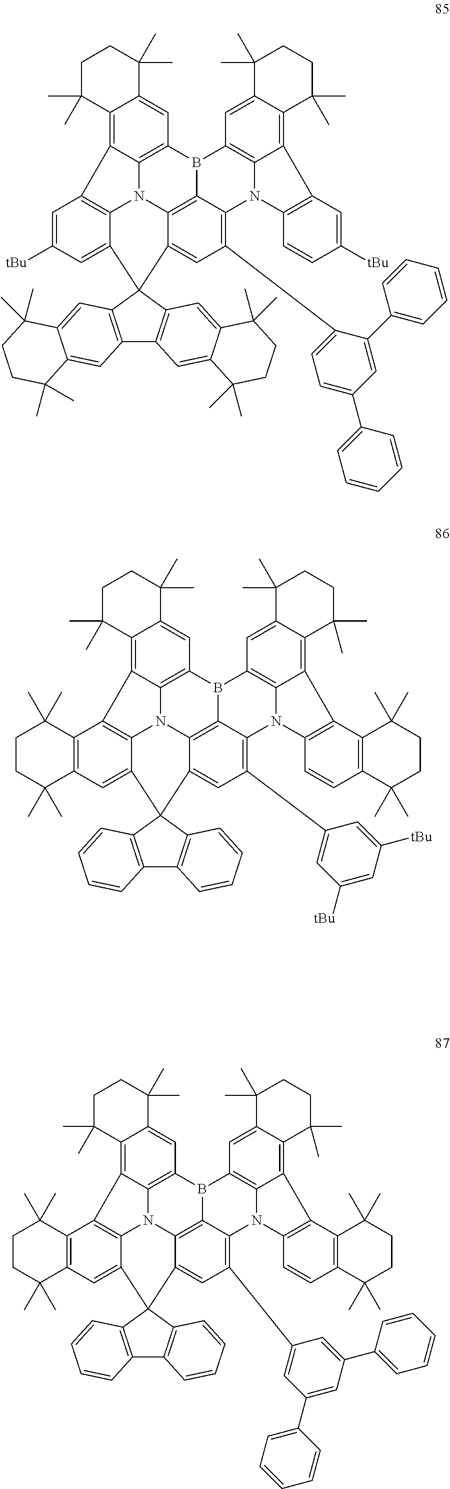

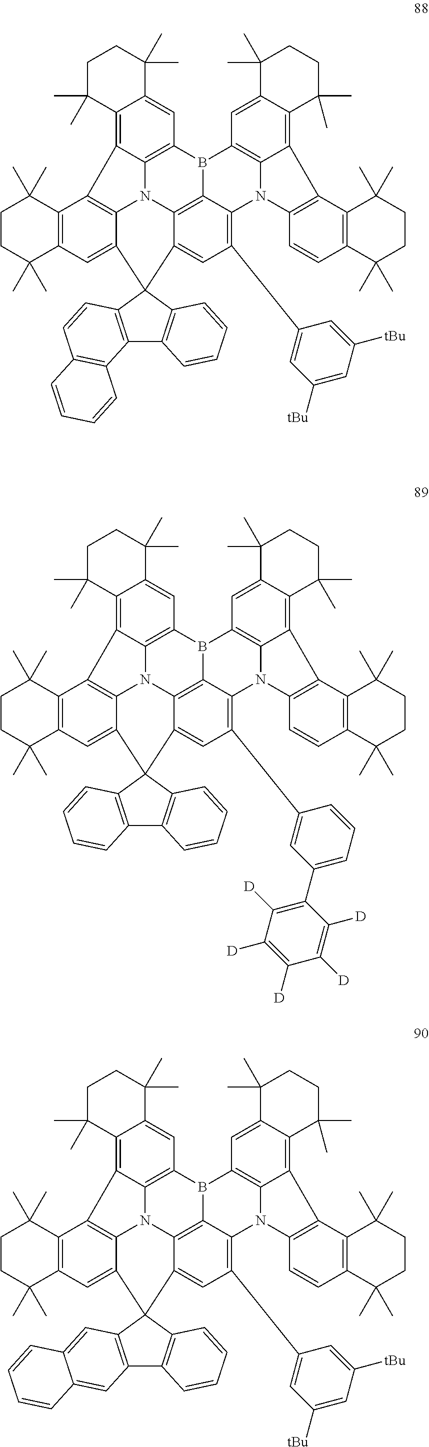

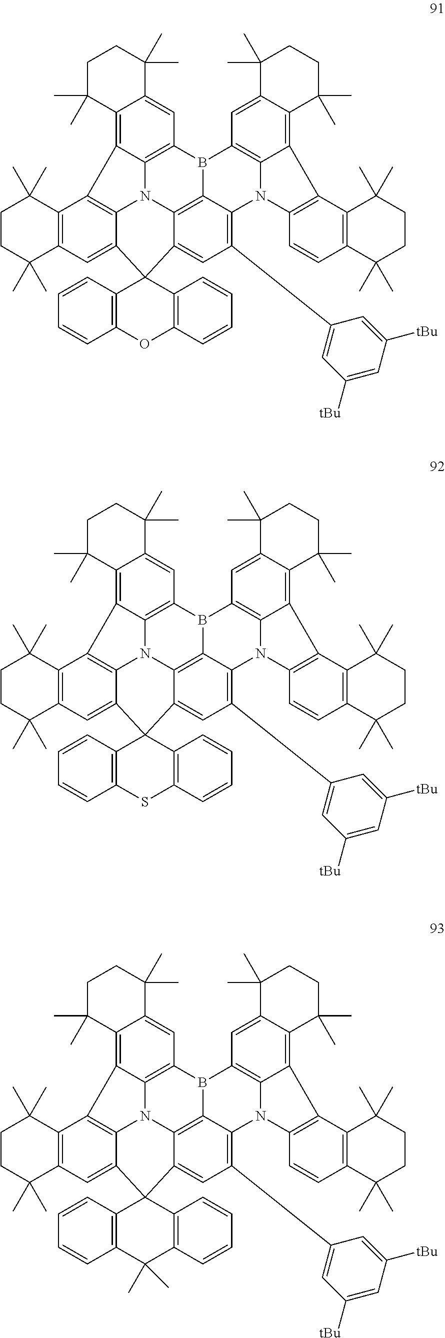

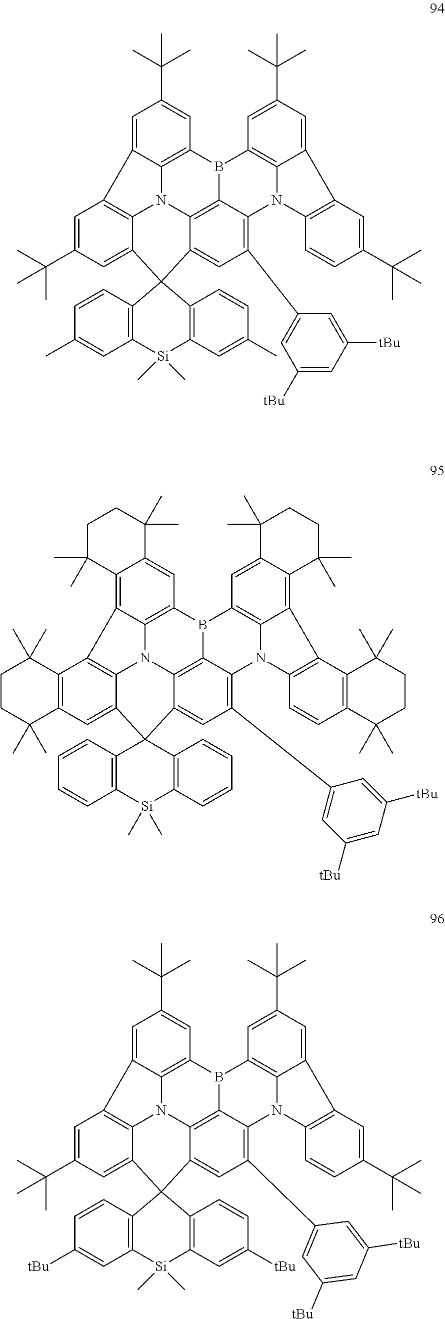

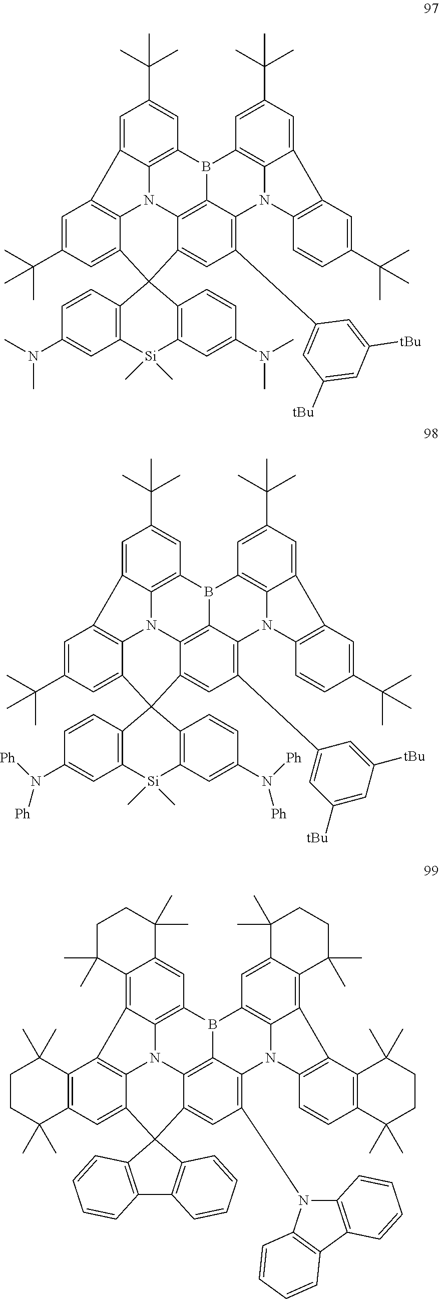

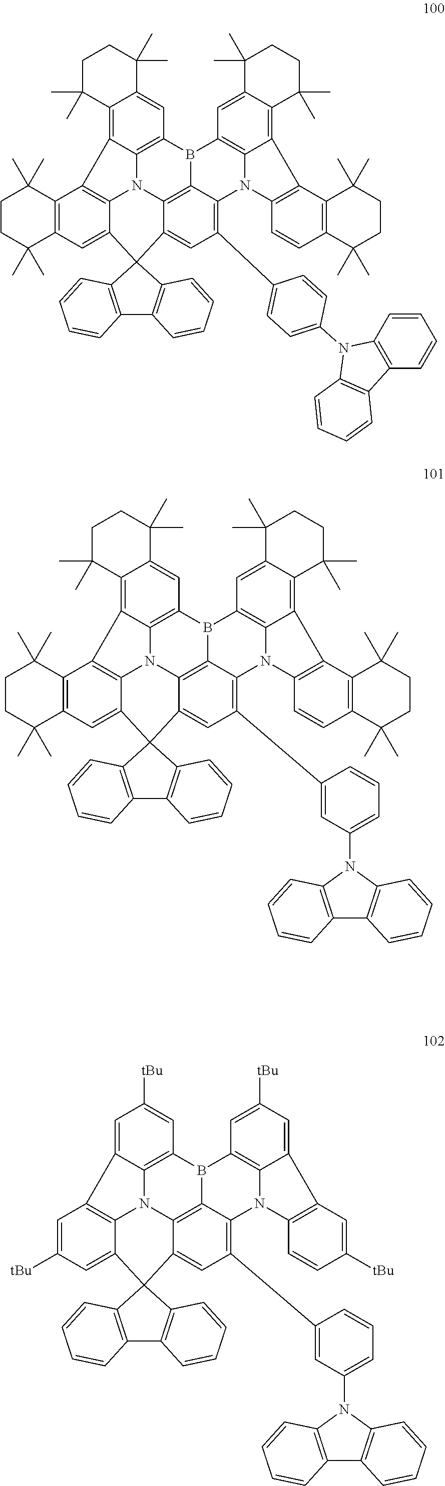

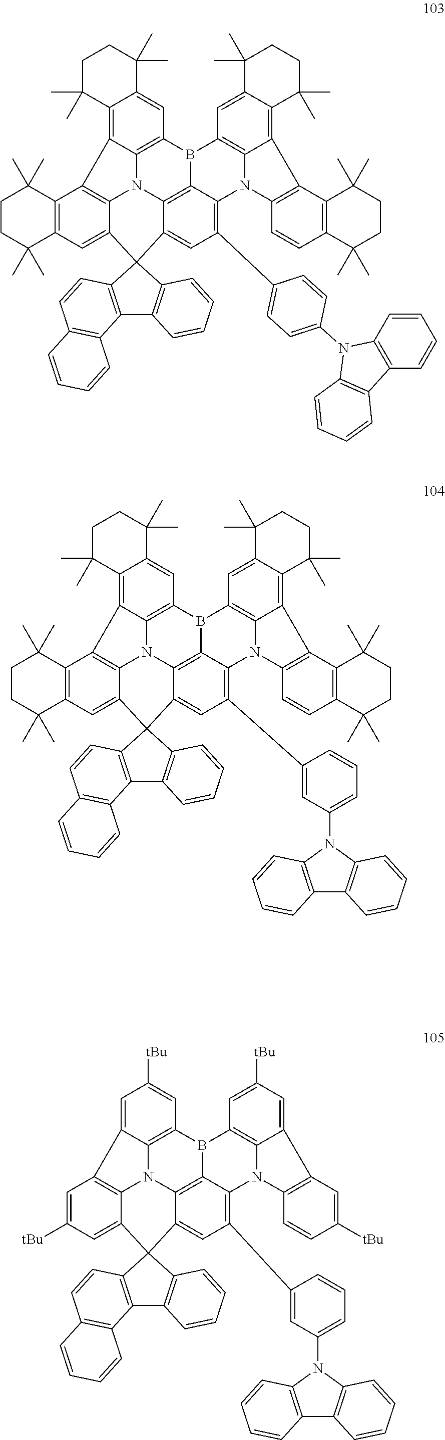

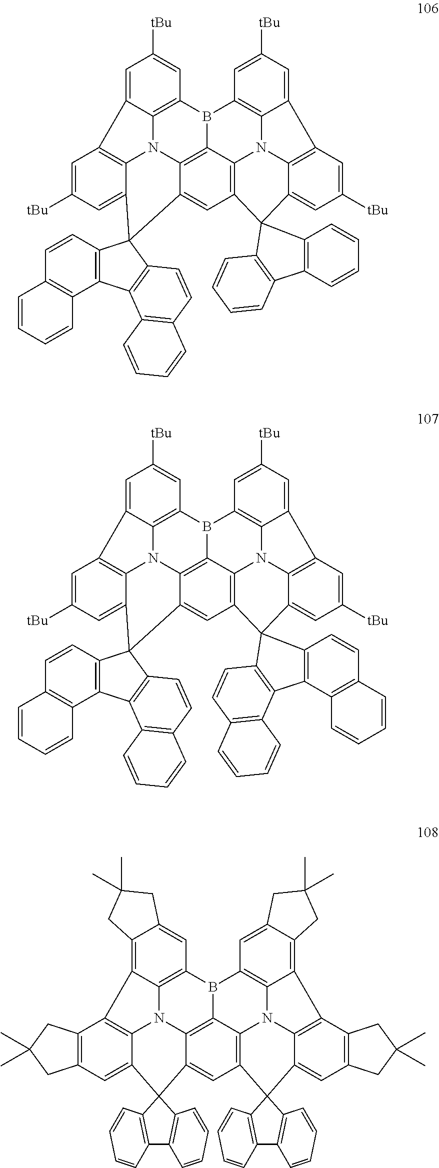

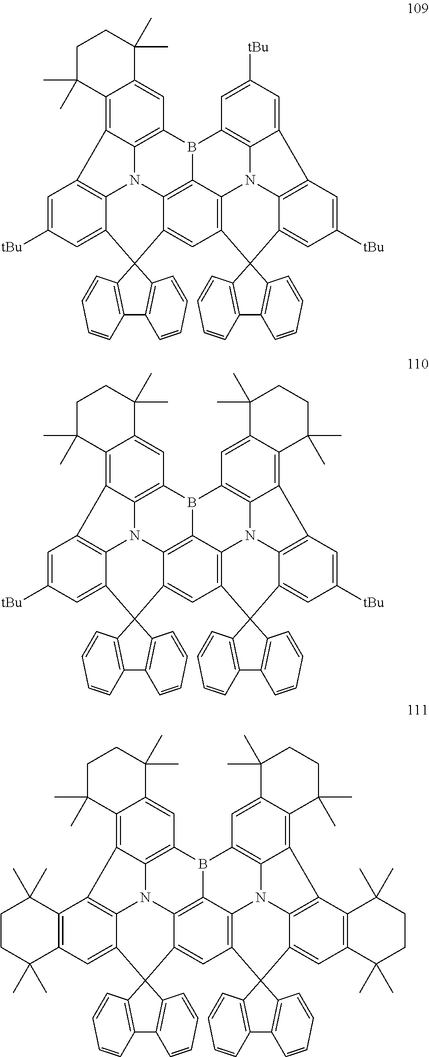

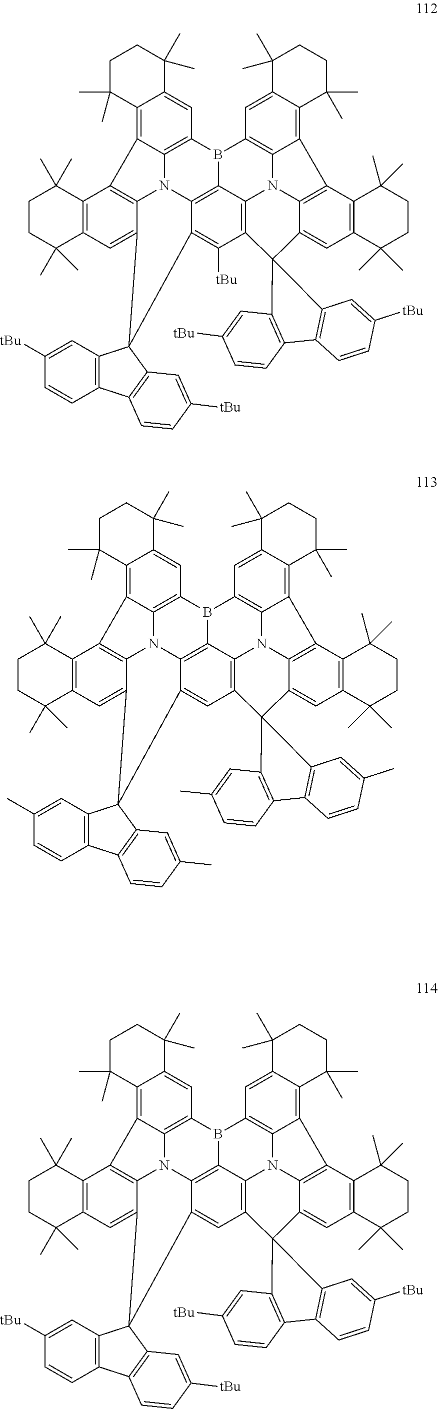

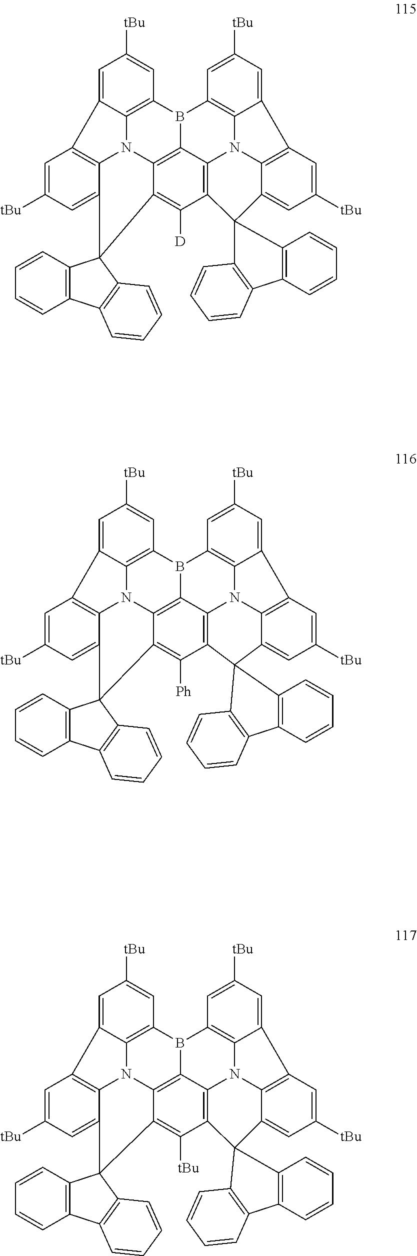 [SMILES: [2H]c1c2c3c4c5c1C1(c6ccccc6-c6ccccc61)c1cc(C(C)(C)C)cc6c7cc(C(C)(C)C)cc(c7n-5c16)B4c1cc(C(C)(C)C)cc4c5cc(C(C)(C)C)cc(c5n-3c14)C21c2ccccc2-c2ccccc21 ; CC(C)(C)c1cc2c3c(c1)c1cc(C(C)(C)C)cc4c1n3-c1c3c5c(c(-c6ccccc6)c1C41c4ccccc4-c4ccccc41)C1(c4ccccc4-c4ccccc41)c1cc(C(C)(C)C)cc4c6cc(C(C)(C)C)cc(c6n-5c14)B32 ; CC(C)(C)c1cc2c3c(c1)c1cc(C(C)(C)C)cc4c1n3-c1c3c5c(c(C(C)(C)C)c1C41c4ccccc4-c4ccccc41)C1(c4ccccc4-c4ccccc41)c1cc(C(C)(C)C)cc4c6cc(C(C)(C)C)cc(c6n-5c14)B32]

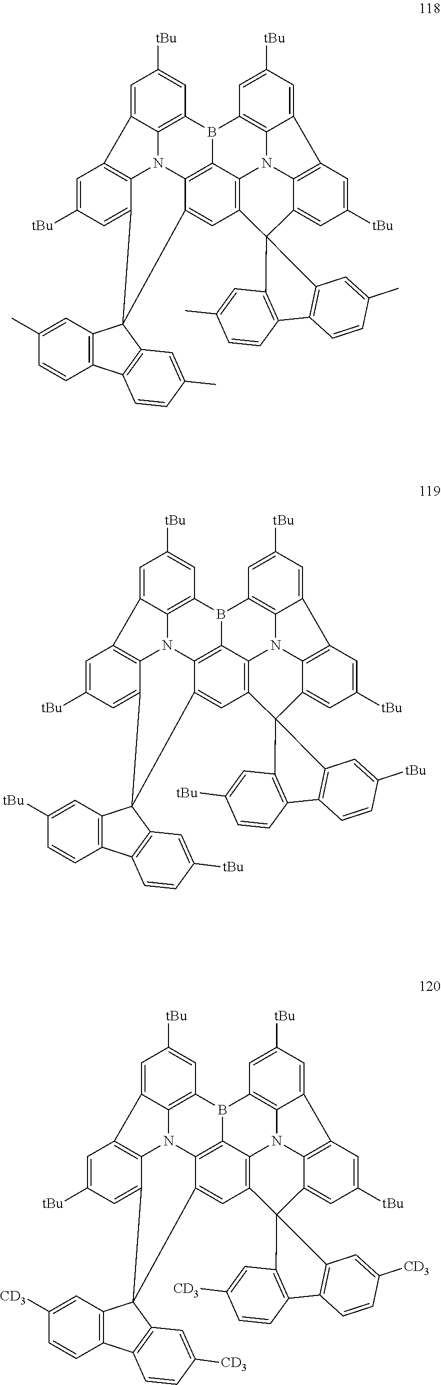

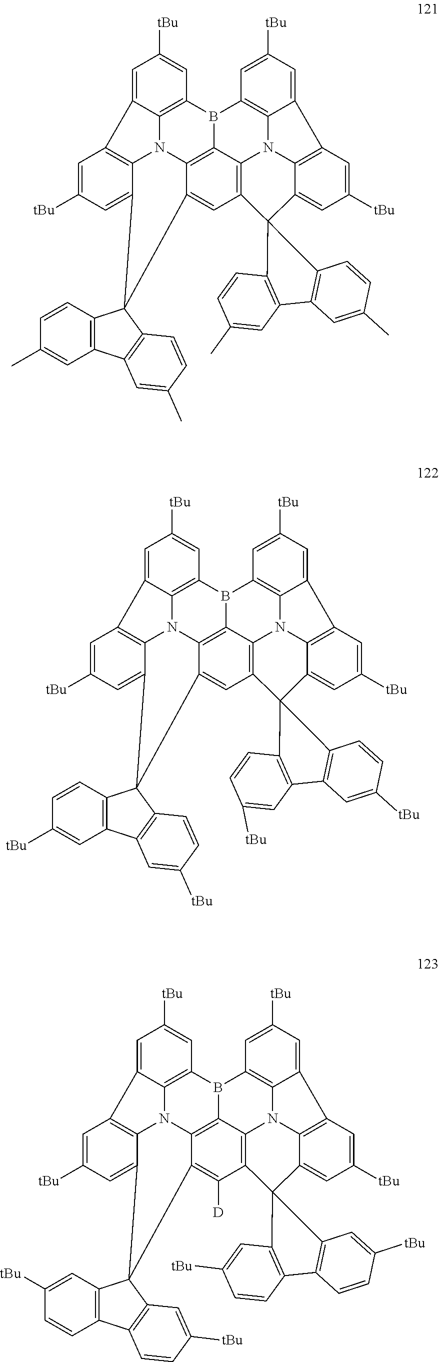

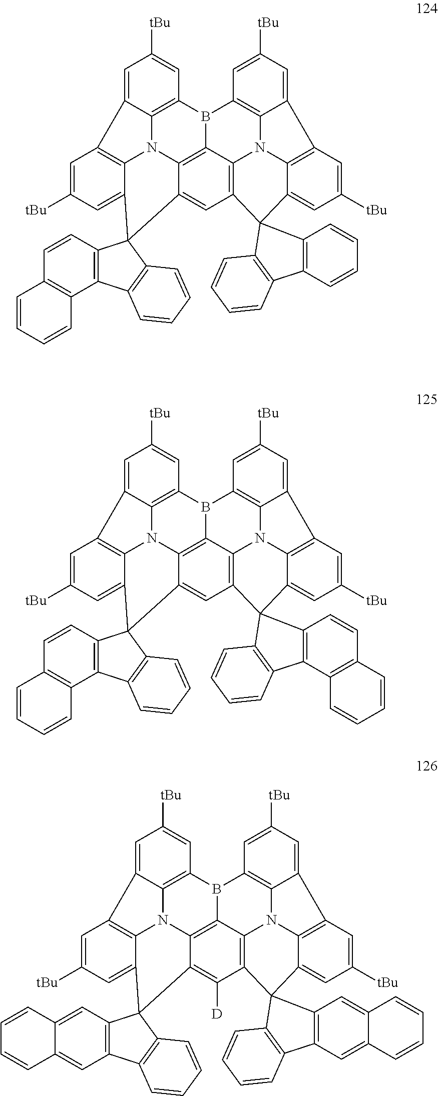 [SMILES: CC(C)(C)c1cc2c3c(c1)c1cc(C(C)(C)C)cc4c1n3-c1c(cc3c5c1B2c1cc(C(C)(C)C)cc2c6cc(C(C)(C)C)cc(c6n-5c12)C31c2ccccc2-c2c1ccc1ccccc21)C41c2ccccc2-c2ccccc21 ; CC(C)(C)c1cc2c3c(c1)c1cc(C(C)(C)C)cc4c1n3-c1c(cc3c5c1B2c1cc(C(C)(C)C)cc2c6cc(C(C)(C)C)cc(c6n-5c12)C31c2ccccc2-c2c1ccc1ccccc21)C41c2ccccc2-c2c1ccc1ccccc21 ; [2H]c1c2c3c4c5c1C1(c6ccccc6-c6cc7ccccc7cc61)c1cc(C(C)(C)C)cc6c7cc(C(C)(C)C)cc(c7n-5c16)B4c1cc(C(C)(C)C)cc4c5cc(C(C)(C)C)cc(c5n-3c14)C21c2ccccc2-c2cc3ccccc3cc21]

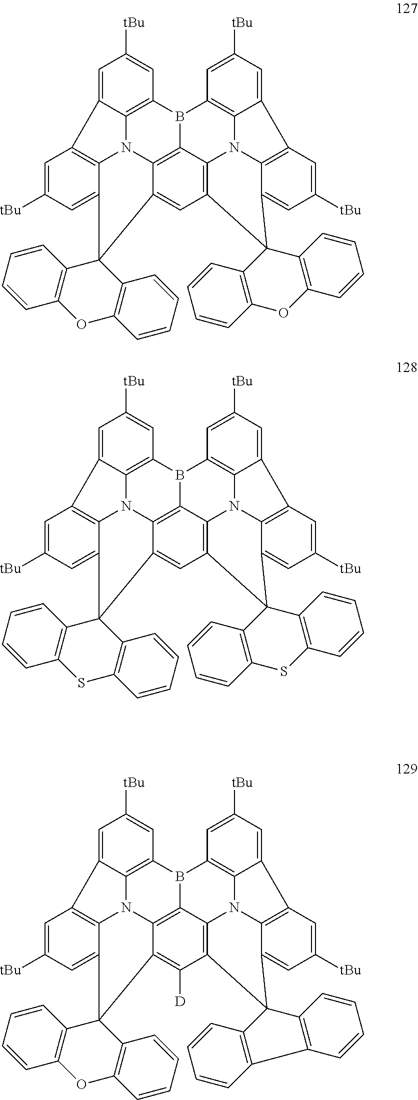

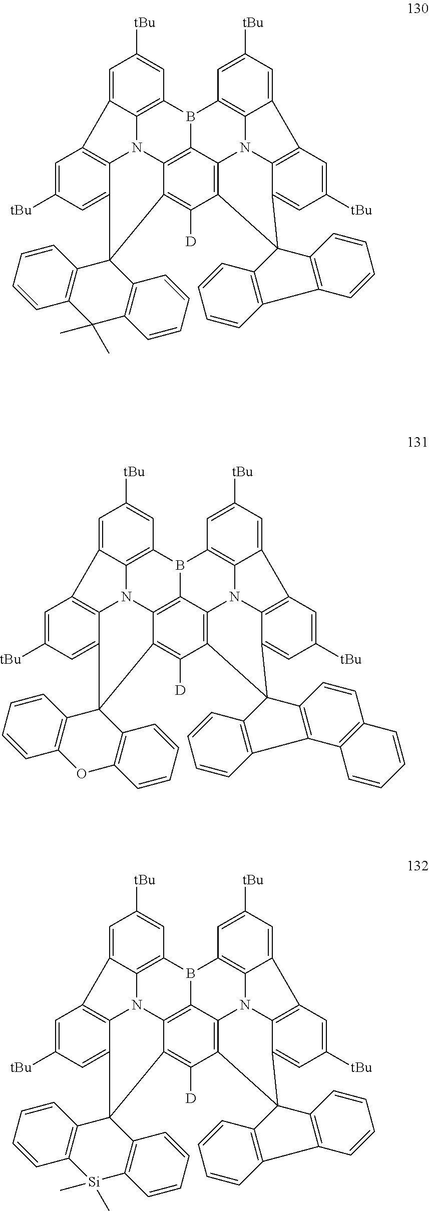 [SMILES: [2H]c1c2c3c4c5c1C1(c6ccccc6C(C)(C)c6ccccc61)c1cc(C(C)(C)C)cc6c7cc(C(C)(C)C)cc(c7n-5c16)B4c1cc(C(C)(C)C)cc4c5cc(C(C)(C)C)cc(c5n-3c14)C21c2ccccc2-c2ccccc21 ; [2H]c1c2c3c4c5c1C1(c6ccccc6-c6c1ccc1ccccc61)c1cc(C(C)(C)C)cc6c7cc(C(C)(C)C)cc(c7n-5c16)B4c1cc(C(C)(C)C)cc4c5cc(C(C)(C)C)cc(c5n-3c14)C21c2ccccc2Oc2ccccc21 ; [2H]c1c2c3c4c5c1C1(c6ccccc6[Si](C)(C)c6ccccc61)c1cc(C(C)(C)C)cc6c7cc(C(C)(C)C)cc(c7n-5c16)B4c1cc(C(C)(C)C)cc4c5cc(C(C)(C)C)cc(c5n-3c14)C21c2ccccc2-c2ccccc21]

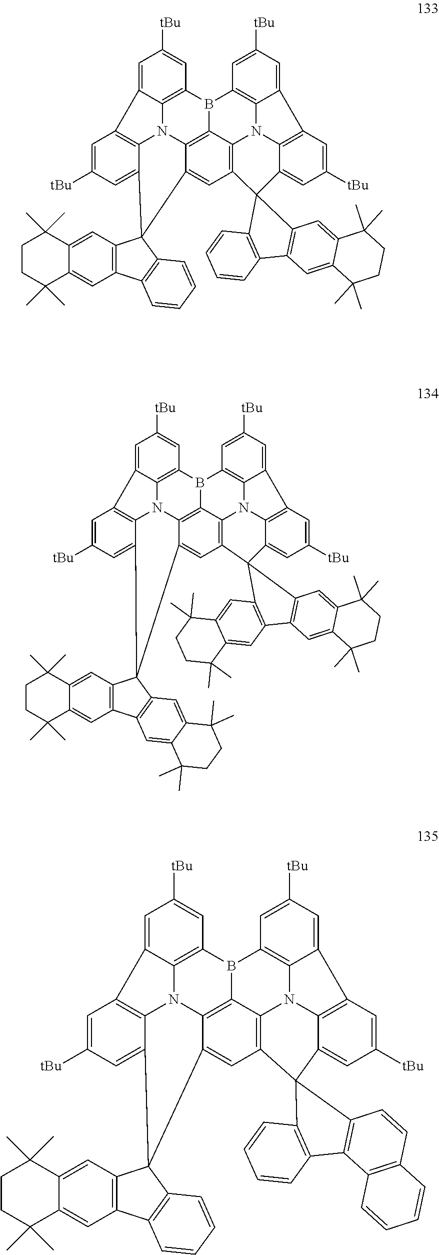

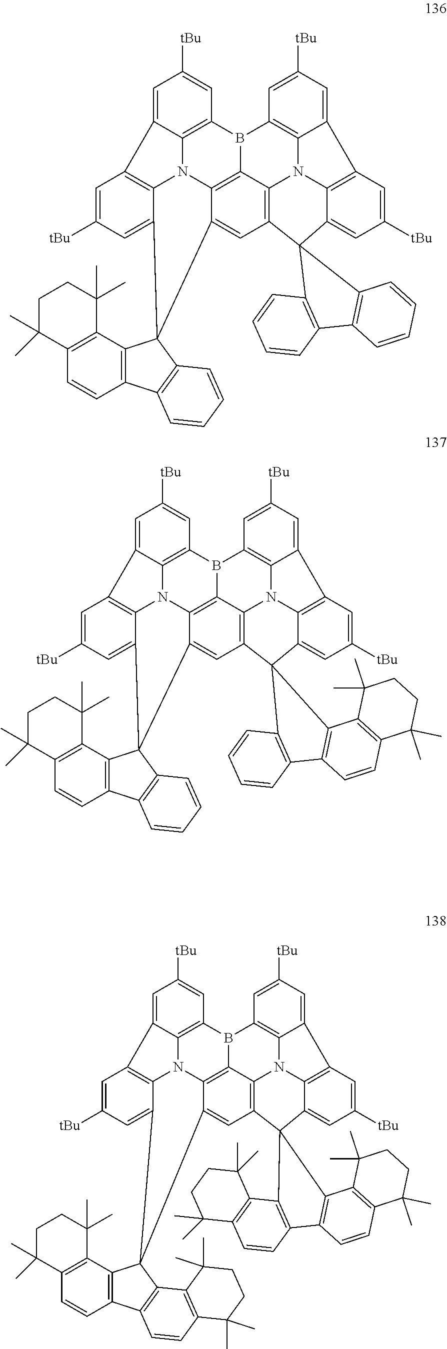

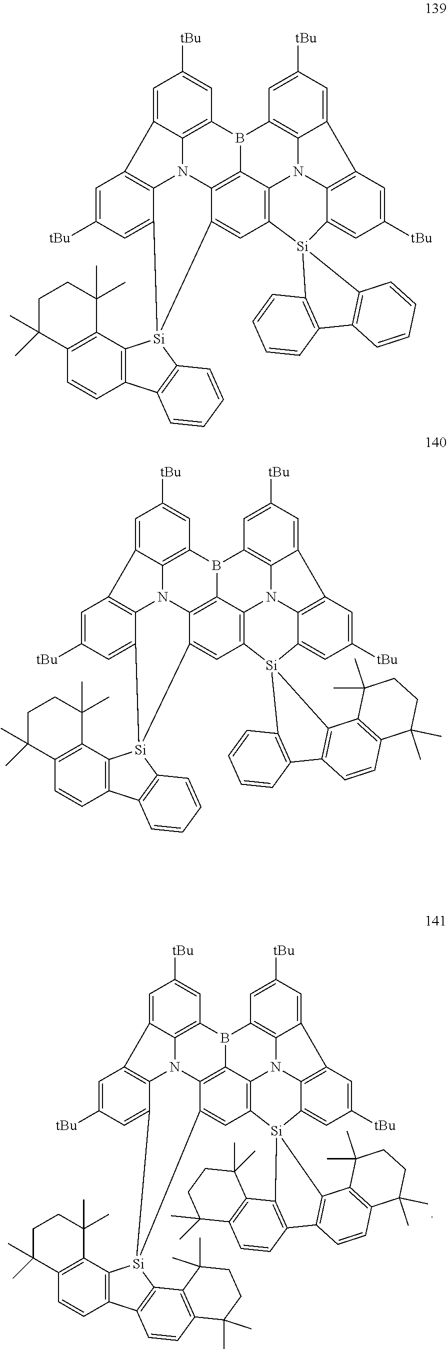

Here, tBu represents a tert-butyl group, Ph represents a phenyl group, and Ad represents an adamantyl group.

The present disclosure further provides an application of the boron-nitrogen compound with the multi-membered fused ring according to any one of the above embodiments in preparation of an organic electroluminescent device.

The present disclosure further provides an organic electroluminescent device. The organic electroluminescent device includes:
a substrate;
a first electrode, disposed on the substrate;
an organic light-emitting functional layer, disposed on the first electrode; and
a second electrode, disposed on the organic light-emitting functional layer.

The organic light-emitting functional layer includes a light-emitting layer. The light-emitting layer includes the boron-nitrogen compound with the multi-membered fused ring according to any one of the above embodiments.

The present disclosure further provides a composition. The composition contains the boron-nitrogen compound with the multi-membered fused ring as shown in formula I.

The present disclosure further provides a preparation. The preparation contains: the boron-nitrogen compound with the multi-membered fused ring as shown in formula I or the above composition, and at least one solvent. The solvent is not particularly limited, and may be used, for example, an unsaturated hydrocarbon solvent, a halogenated saturated hydrocarbon solvent, a halogenated unsaturated hydrocarbon solvent, an ether solvent or an ester solvent as known to a person skilled in the art. The unsaturated hydrocarbon solvent is toluene, xylene, mesitylene, tetralin, n-butylbenzene, sec-butylbenzene or tert-butylbenzene. The halogenated saturated hydrocarbon solvent is carbon tetrachloride, chloroform, dichloromethane, dichloroethane, chlorobutane, bromobutane, chloropentane, bromopentane, chlorohexane, bromohexane, chlorocyclohexane or bromocyclohexane. The halogenated unsaturated hydrocarbon solvent is chlorobenzene, dichlorobenzene or trichlorobenzene. The ether solvents is tetrahydrofuran or tetrahydropyran. The ester solvent is alkyl benzoate.

The organic electroluminescent device in the present disclosure may be used in a display or lighting apparatus. In some embodiments, the organic electroluminescent device fabricated by the present disclosure is used in smart phones, tablet computers, smart wearable devices, televisions, virtual reality (VR) devices, micro-display fields, automobile center control screens and automobile rear lamps.

The present disclosure further provides a display or lighting apparatus. The display or lighting apparatus includes one or more organic electroluminescent devices each according to the above embodiments.

In summary, compared with the prior art, the present disclosure has the following beneficial effects:
in the present disclosure, the boron-nitrogen compound has a large conjugate system by combining a boron-nitrogen fused heterocyclic structure with a spirocyclic fragment; by means of modification with alkyl and cycloalkyl groups, the spatial three-dimensionality of a structure can be increased; and the structure as a whole has a good thermal stability and film-forming properties, and show good hole and electron transport capacities, which may effectively improve the energy transfer performance between a host material and a guest material. By using the boron-nitrogen compound provided by the present disclosure to fabricate an organic light-emitting device, it may be possible to effectively enable the organic light-emitting device to have a low driving voltage, maintain the voltage stability, and improve the light-emitting efficiency, and the working lifespan of the light-emitting device may also be relatively long.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person having ordinary skill in the art can obtain other drawings according to these accompanying drawings. In addition, the accompanying drawings in the following description may be regarded as schematic diagrams, and are not limitations to actual sizes of products, actual processes of methods or actual timings of signals to which the embodiments of the present disclosure relate.

FIG. 1 is a structural diagram of an organic electroluminescent device in accordance with some embodiments of the present disclosure;

FIG. 2 is a structural diagram of an organic light-emitting diode (OLED) device in accordance with some embodiments of the present disclosure; and

FIG. 3 is a structural diagram of another OLED device in accordance with some embodiments of the present disclosure.

### DETAILED DESCRIPTION

Technical solutions of the present disclosure will be described clearly and completely by using embodiments below. However, the described embodiments are merely some but not all embodiments of the present disclosure. On the basis of the embodiments of the present disclosure, all other embodiments obtained by a person of ordinary skill in the art without making creative labour shall be included in the protection scope of the present disclosure.

The term “alkyl” or “alkyl group” means and includes both linear alkyl groups and branched alkyl groups. For example, alkyl groups are alkyl groups containing 1 to 20 carbon atoms, and include a methyl group, an ethyl group, a propyl group, a 1-methylethyl group, a butyl group, a 1-methylpropyl group, a 2-methylpropyl group, a pentyl group, a 1-methylbutyl group, a 2-methylbutyl group, a 3-methylbutyl group, a 1,1-dimethylpropyl group, a 1,2-dimethylpropyl group, a 2,2-dimethylpropyl group, etc. In addition, an alkyl group may optionally be substituted.

The term “cycloalkyl” or “cycloalkyl group” means and includes monocycloalkyl groups, polycycloalkyl groups and spiroalkyl groups. For example, cycloalkyl groups are cycloalkyl groups containing 3 to 20 ring carbon atoms. For example, the cycloalkyl groups are cycloalkyl groups containing 3 to 12 ring carbon atoms. For example, the cycloalkyl groups are cycloalkyl groups containing 3 to 6 ring carbon atoms. For example, the cycloalkyl groups include a cyclopropyl group, a cyclopentyl group, a cyclohexyl group, a bicyclo[3.1.1]heptyl group, a spiro[4.5]decyl group, a spiro[5.5]undecyl group, an adamantyl group, etc. In addition, a cycloalkyl group may optionally be substituted.

The term “aryl” or “aryl group” means and includes monocyclic aromatic hydrocarbon groups and polycyclic aromatic ring systems. A polycyclic aromatic ring system may have two or more rings in which two carbons are shared by two adjacent rings (which are “fused”); and at least one of the two or more rings is an aromatic hydrocarbon group, and the other rings may be, for example, a cycloalkyl group, a cycloalkenyl group, an aryl group, a heterocyclic group, and/or a heteroaryl group. For example, aryl groups are aryl groups containing six to thirty carbon atoms. For example, the aryl groups are aryl groups containing six to twelve carbon atoms. For example, the aryl groups are aryl groups having six, ten or twelve carbons. Suitable aryl groups include a phenyl, a biphenyl group, a terphenyl group, a triphenylenyl group, a tetraphenylene group, a naphthyl group, an anthryl group, a phenalene group, a phenanthryl group, a fluorenyl group, a pyrenyl group, a perylenyl group and an azulenyl group. For example, the aryl groups include a phenyl group, a biphenyl group, a terphenyl group, a triphenylenyl group, a fluorenyl group and a naphthyl group. In addition, an aryl group may optionally be substituted.

The heteroaryl group is a generic term for groups obtained by substitution of one or more aromatic nucleus carbons of an aryl group by heteroatom(s), a heteroatom including but being not limited to an oxygen atom, a sulfur atom, a silicon atom or a nitrogen atom. The heteroaryl group may be a monocyclic heteroaryl group or a fused ring heteroaryl group. For example, the heteroaryl group may be a heteroaryl group having 5 to 36 carbon atoms. For example, the heteroaryl group may be a heteroaryl group having 6 to 20 carbon atoms. Examples for heteroaryl groups may include but are not limited to a pyridyl group, a pyrrolyl group, a thienyl group, a furanyl group, an indolyl group, a quinolyl group, an isoquinolyl group, a benzothienyl group, a benzofuranyl group, a dibenzofuranyl group, a dibenzothienyl group, a carbazolyl group, etc., but not limited thereto.

In the present disclosure, the term “optionally” means that an event or a circumstance subsequently described may or may not occur. For example, the expression “optionally, any two adjacent substituents forming a ring” means that the two substituents may or may not form a ring, i.e., including: a case where the two adjacent substituents form a ring, and another case where the two adjacent substituents do not form a ring. The expression “any two adjacent substituents” may include both a case of two substituents on a same atom and another case of two substituents on two respective adjacent atoms. In the case of the two substituents on the same atom, the two substituents may form, together with the co-connected atom, a saturated or unsaturated spirocycle; and in the another case of the two substituents on the two respective adjacent atoms, the two substituents may be fused into a ring.

Throughout the description, unless explicitly described to the contrary, the expression “including/comprising” any component are construed as implying the inclusion of other element(s), but not the exclusion of any other element. In addition, it will be understood that, throughout the description, when an element such as a layer, a film, a region or a substrate is described as being “on” or “above” another element, the element may be “directly on” the another element, or there may be intermediate element(s) between the element and the another element. Furthermore, the term “on” or “above” means being located on a side of a target portion, but does not necessarily mean being located above the target portion in a direction of gravity.

The phrase “A and/or B” includes the following three combinations: only A, only B, and a combination of A and B.

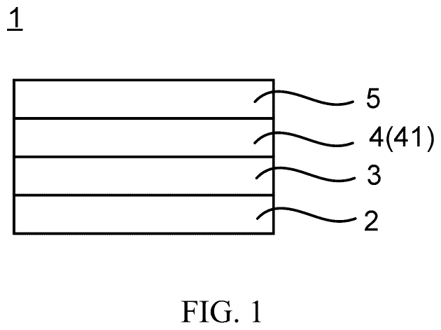

An object of the present disclosure is to provide an organic electroluminescent device. With reference to FIG. 1, the organic electroluminescent device 1 includes: a substrate 2, a first electrode 3 disposed on the substrate 1, an organic light-emitting function layer 4 disposed on the first electrode 3, and a second electrode 5 disposed on the organic light-emitting function layer 4. The organic light-emitting function layer 4 includes a light-emitting layer 41. The light-emitting layer 41 includes a boron-nitride compound with a multi-membered fused ring.

In one embodiment of the present disclosure, the light-emitting layer 41 of the organic electroluminescent device 1 (also referred to as a light-emitting diode, abbreviated as an OLED) includes one or more of compounds each as shown in general formula I above as a light-emitting dopant material (also referred to as a guest material).

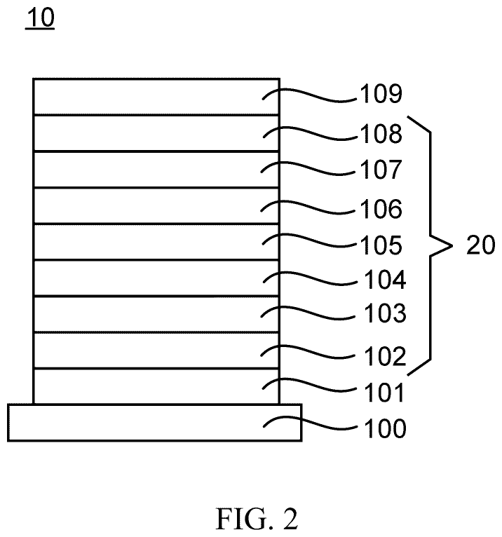

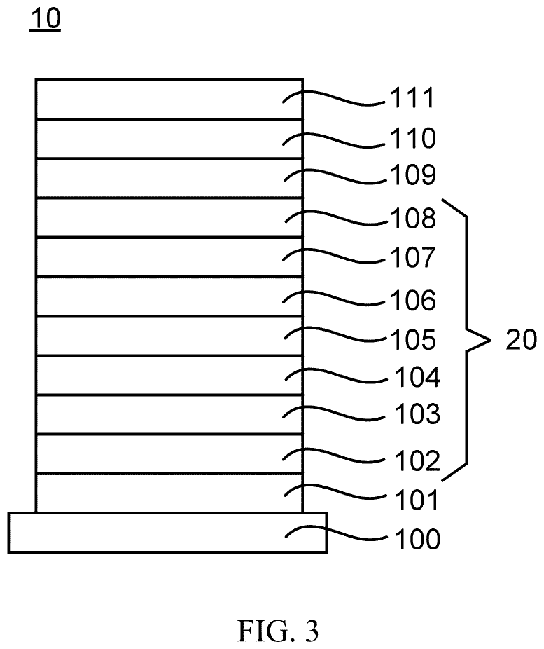

With reference to FIG. 2, an embodiment of the present disclosure provides an OLED device 10. The OLED device 10 includes a substrate 100, an anode 101 disposed on the substrate 100, an organic light-emitting functional layer 20 disposed on a side of the anode 101 away from the substrate 100, and a cathode 109 disposed on a side of the organic light-emitting functional layer 20 away from the substrate 100. The organic light-emitting functional layer 20 may include a hole injection layer 102, a hole transport layer 103, an electron blocking layer 104, a light-emitting layer 105, a hole blocking layer 106, an electron transport layer 107 and an electron injection layer 108 which are stacked in a direction away from the substrate 100 in sequence. Alternatively, the organic light-emitting functional layer 20 may include only a light-emitting layer and one or more other layers. The light-emitting layer 105 contains a light-emitting dopant material composed of one or more of compounds each as shown in the above general formula (I). In some embodiments, with reference to FIG. 3, a cover layer 110, a protective layer and/or an encapsulation layer 111 are further provided on the organic light-emitting functional layer 20.

The substrate in the present disclosure may be any substrate selected from substrates applied in typical organic light-emitting apparatuses. The substrate may be a glass substrate or a transparent plastic substrate, or may be a substrate of an opaque material such as silicon or stainless steel, or may be a flexible polyimide (PI) film. Different substrates are different in mechanical strength, thermal stability, transparency, surface smoothness and waterproofness; and depending on natures of the different substrates, the different substrates are used in different directions.

In some embodiments of the present disclosure, the OLED device includes a hole injection layer. A P-type dopant material in the hole injection layer may be selected from known or unknown materials. For example, the P-type dopant material is selected from materials having following structures:

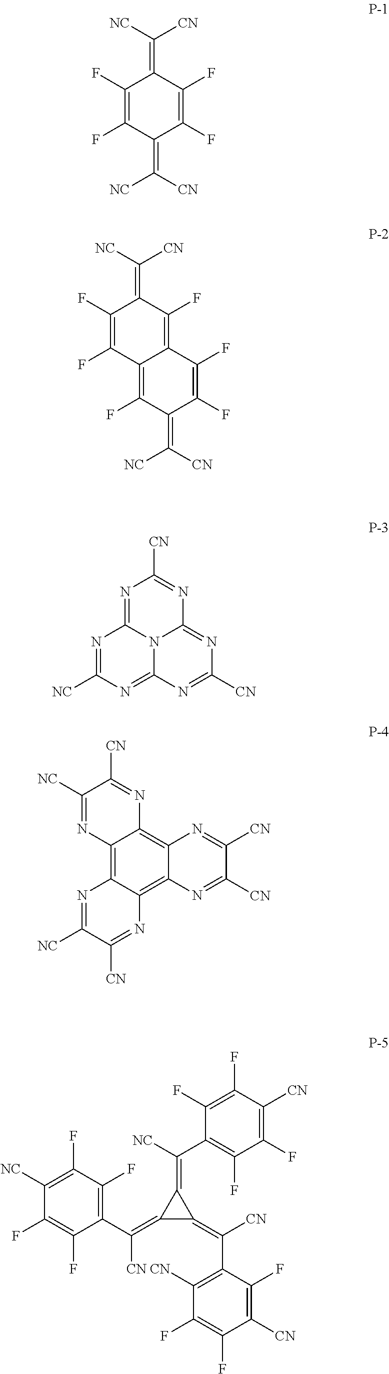

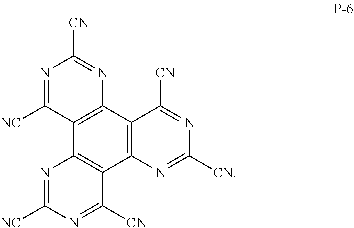 [SMILES: N#Cc1nc(C#N)c2c(n1)c1c(C#N)nc(C#N)nc1c1c(C#N)nc(C#N)nc21]

However, embodiments of the present disclosure are limited thereto.

In some embodiments of the present disclosure, the OLED device includes a hole transport layer. A material of the hole transport layer may be selected from known or unknown materials. For example, the material of the hole transport layer is selected from following structures:

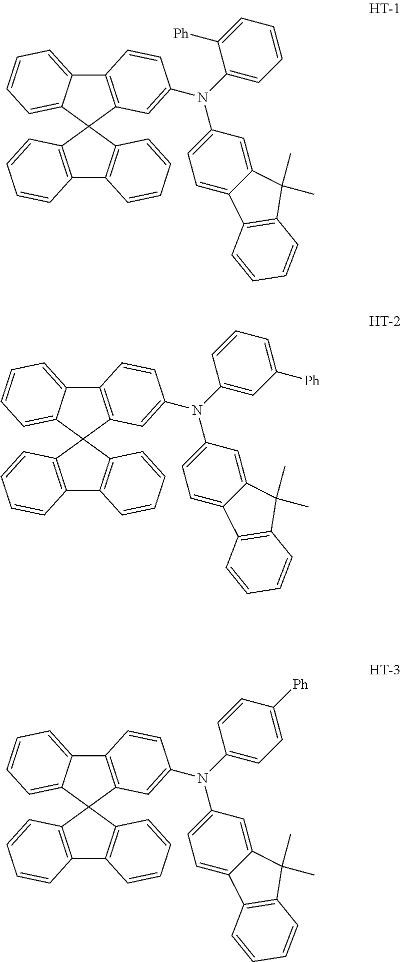 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

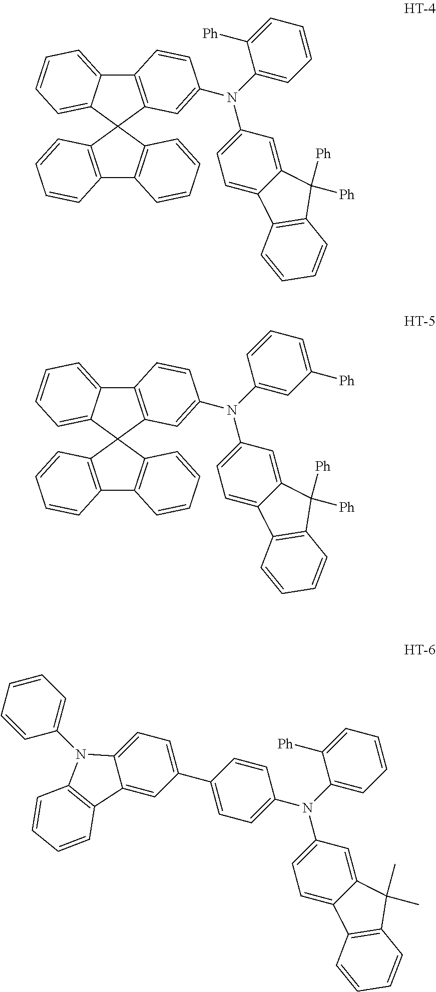 [SMILES: c1ccc(-c2ccccc2N(c2ccc3c(c2)C(c2ccccc2)(c2ccccc2)c2ccccc2-3)c2ccc3c(c2)C2(c4ccccc4-c4ccccc42)c2ccccc2-3)cc1 ; c1ccc(-c2cccc(N(c3ccc4c(c3)C(c3ccccc3)(c3ccccc3)c3ccccc3-4)c3ccc4c(c3)C3(c5ccccc5-c5ccccc53)c3ccccc3-4)c2)cc1 ; CC1(C)c2ccccc2-c2ccc(N(c3ccc(-c4ccc5c(c4)c4ccccc4n5-c4ccccc4)cc3)c3ccccc3-c3ccccc3)cc21]

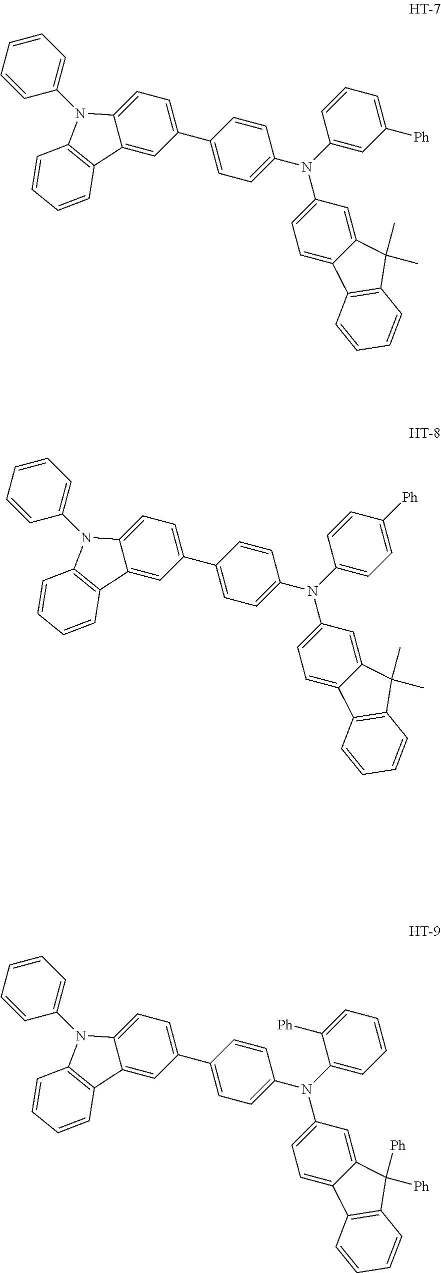 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccccc2N(c2ccc(-c3ccc4c(c3)c3ccccc3n4-c3ccccc3)cc2)c2ccc3c(c2)C(c2ccccc2)(c2ccccc2)c2ccccc2-3)cc1]

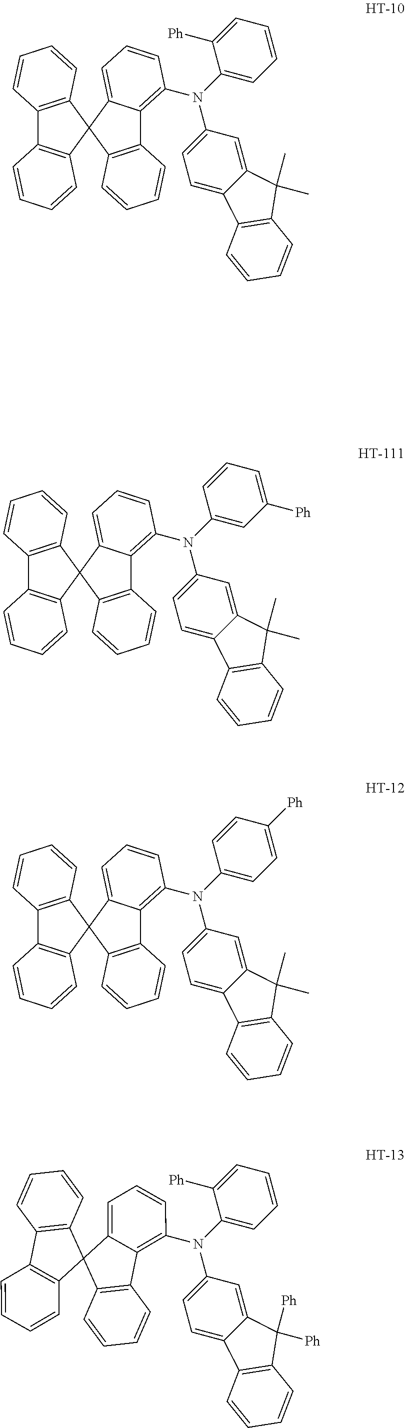 [SMILES: CC1(C)c2ccccc2-c2ccc(N(c3ccccc3-c3ccccc3)c3cccc4c3-c3ccccc3C43c4ccccc4-c4ccccc43)cc21 ; CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccccc2N(c2ccc3c(c2)C(c2ccccc2)(c2ccccc2)c2ccccc2-3)c2cccc3c2-c2ccccc2C32c3ccccc3-c3ccccc32)cc1]

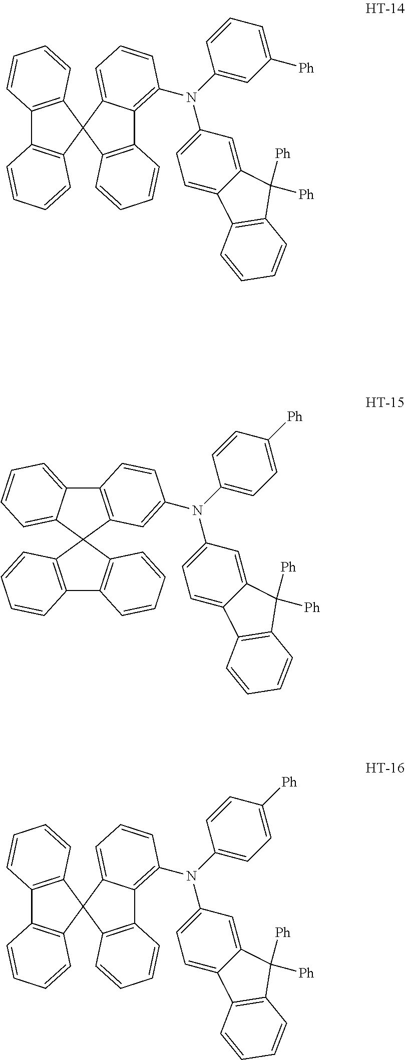 [SMILES: c1ccc(-c2cccc(N(c3ccc4c(c3)C(c3ccccc3)(c3ccccc3)c3ccccc3-4)c3cccc4c3-c3ccccc3C43c4ccccc4-c4ccccc43)c2)cc1 ; c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; c1ccc(-c2ccc(N(c3ccc4c(c3)C(c3ccccc3)(c3ccccc3)c3ccccc3-4)c3cccc4c3-c3ccccc3C43c4ccccc4-c4ccccc43)cc2)cc1]

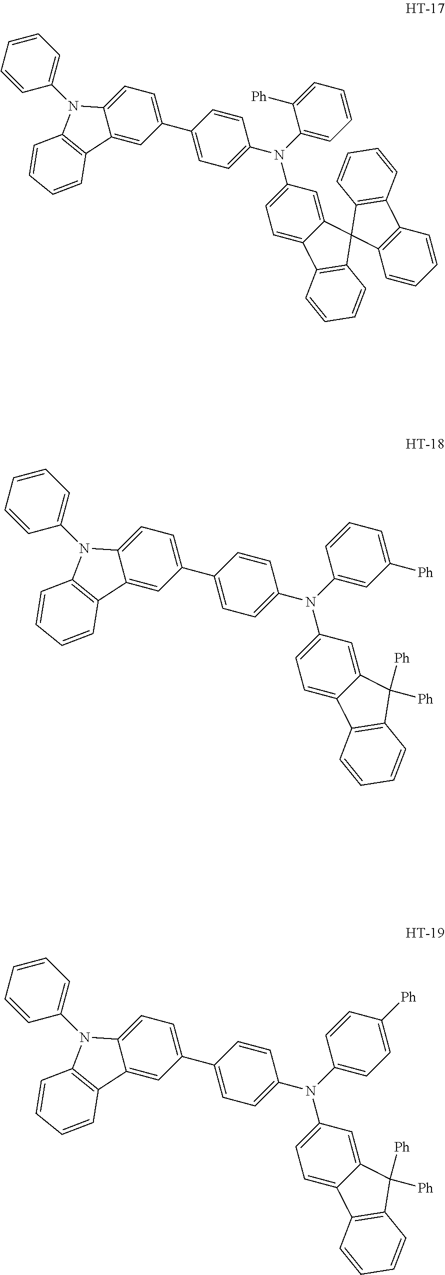 [SMILES: c1ccc(-c2ccccc2N(c2ccc(-c3ccc4c(c3)c3ccccc3n4-c3ccccc3)cc2)c2ccc3c(c2)C2(c4ccccc4-c4ccccc42)c2ccccc2-3)cc1 ; c1ccc(-c2cccc(N(c3ccc(-c4ccc5c(c4)c4ccccc4n5-c4ccccc4)cc3)c3ccc4c(c3)C(c3ccccc3)(c3ccccc3)c3ccccc3-4)c2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

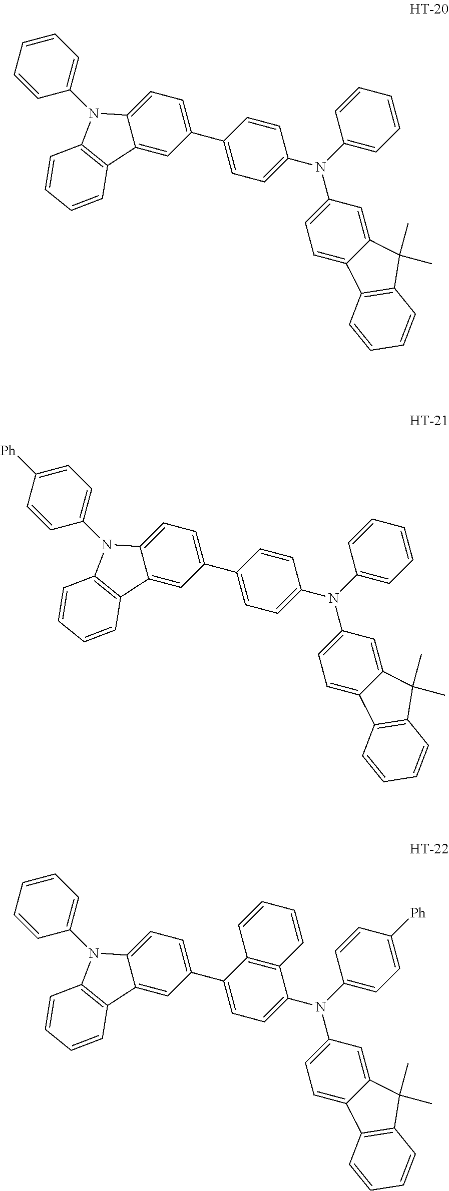 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21]

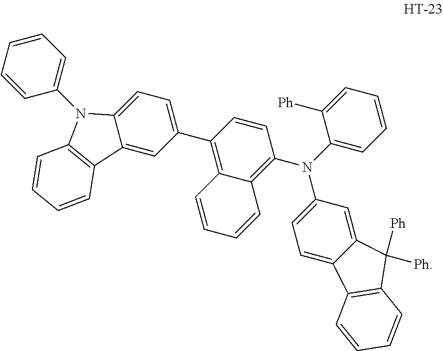 [SMILES: c1ccc(-c2ccccc2N(c2ccc3c(c2)C(c2ccccc2)(c2ccccc2)c2ccccc2-3)c2ccc(-c3ccc4c(c3)c3ccccc3n4-c3ccccc3)c3ccccc23)cc1]

However, embodiments of the present disclosure are limited thereto.

In some embodiments of the present disclosure, the OLED device includes an electron transport layer. A material of the electron transport layer may be selected from known or unknown materials. For example, the material of the electron transport layer is selected from materials having following structures:

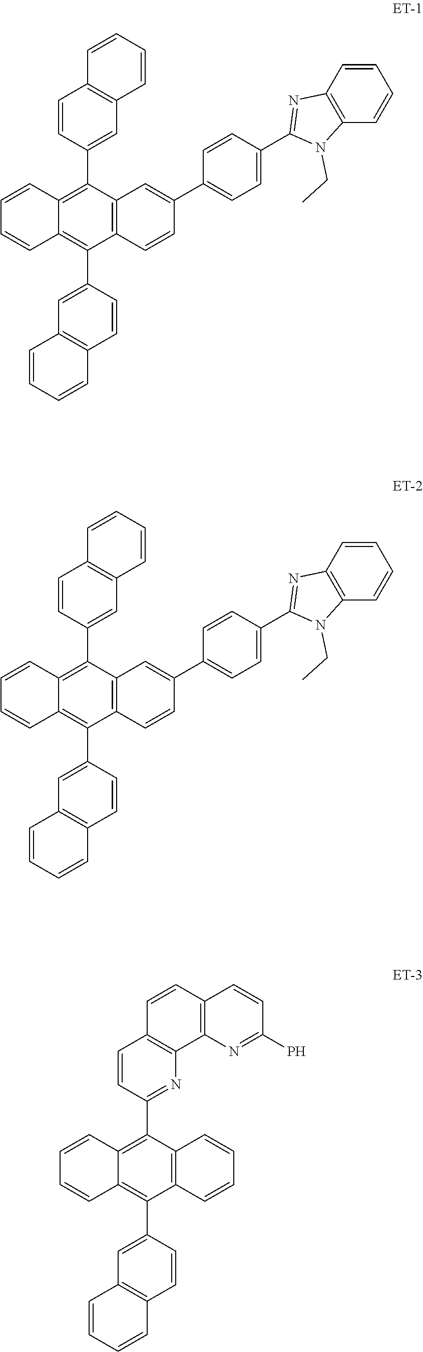

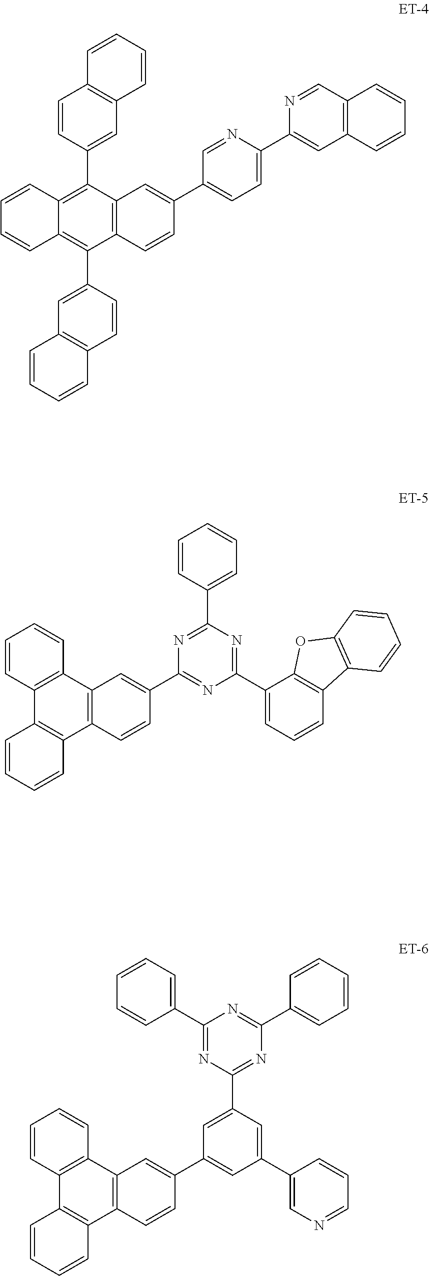 [SMILES: c1ccc2cc(-c3c4ccccc4c(-c4ccc5ccccc5c4)c4cc(-c5ccc(-c6cc7ccccc7cn6)nc5)ccc34)ccc2c1 ; c1ccc(-c2nc(-c3ccc4c5ccccc5c5ccccc5c4c3)nc(-c3cccc4c3oc3ccccc34)n2)cc1 ; c1ccc(-c2nc(-c3ccccc3)nc(-c3cc(-c4cccnc4)cc(-c4ccc5c6ccccc6c6ccccc6c5c4)c3)n2)cc1]

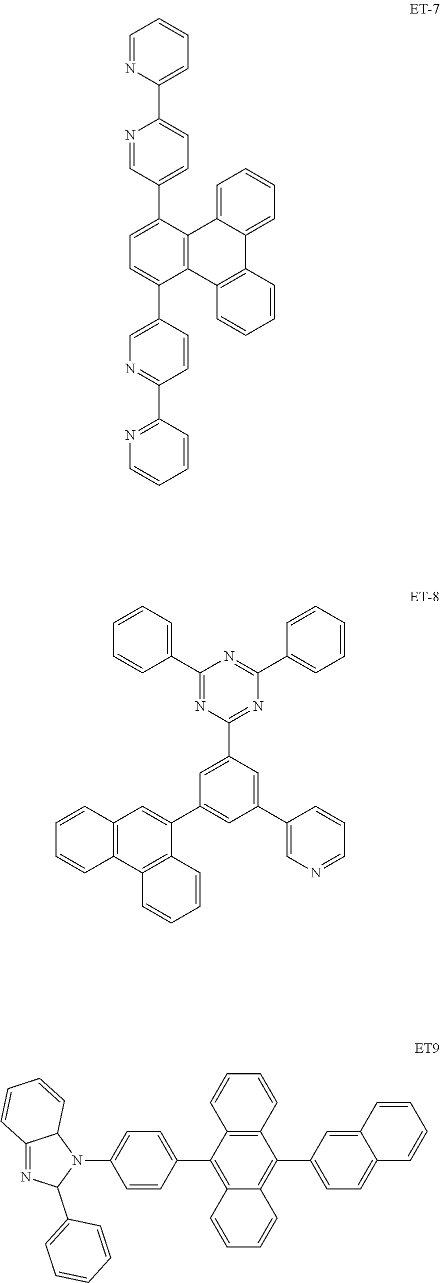 [SMILES: c1ccc(-c2ccc(-c3ccc(-c4ccc(-c5ccccn5)nc4)c4c5ccccc5c5ccccc5c34)cn2)nc1 ; c1ccc(-c2nc(-c3ccccc3)nc(-c3cc(-c4cccnc4)cc(-c4cc5ccccc5c5ccccc45)c3)n2)cc1 ; C1=CC2=NC(c3ccccc3)N(c3ccc(-c4c5ccccc5c(-c5ccc6ccccc6c5)c5ccccc45)cc3)C2C=C1]

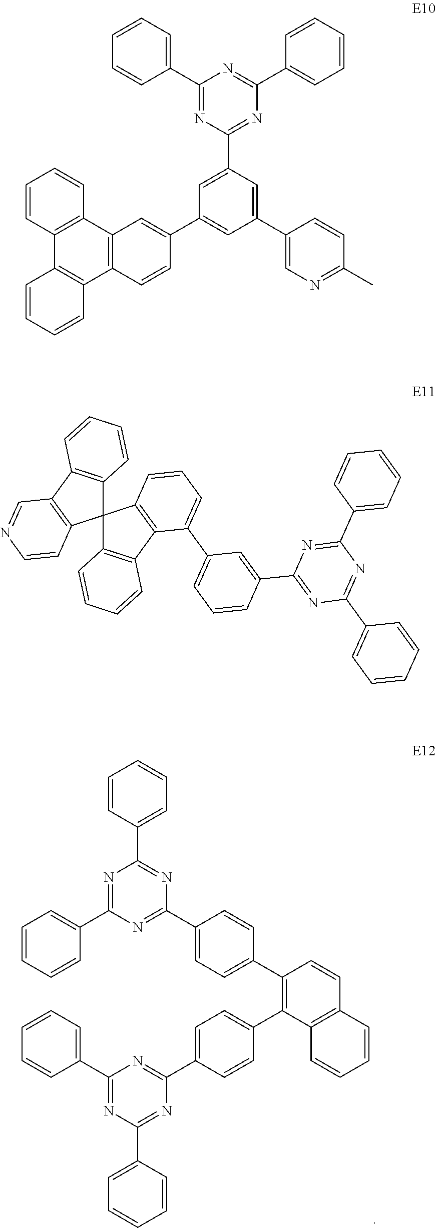 [SMILES: Cc1ccc(-c2cc(-c3ccc4c5ccccc5c5ccccc5c4c3)cc(-c3nc(-c4ccccc4)nc(-c4ccccc4)n3)c2)cn1 ; c1ccc(-c2nc(-c3ccccc3)nc(-c3cccc(-c4cccc5c4-c4ccccc4C54c5ccccc5-c5cnccc54)c3)n2)cc1 ; c1ccc(-c2nc(-c3ccccc3)nc(-c3ccc(-c4ccc5ccccc5c4-c4ccc(-c5nc(-c6ccccc6)nc(-c6ccccc6)n5)cc4)cc3)n2)cc1]

However, embodiments of the present disclosure are limited thereto.

As a host material capable of generating green fluorescence, the host material needs to have not only extremely high fluorescence quantum light-emitting efficiency but also an appropriate energy level, so as to effectively cooperate with a guest material for excitation light-emission. The host material may be selected from known or unknown materials.

Embodiments of the present disclosure are specifically described by means of specific examples below. All raw materials and solvents in synthetic embodiments are purchased commercially unless otherwise specified. The solvents are used directly without further processing.

### EMBODIMENTS

### Embodiment 1: Synthesis of Compound 15

### Synthesis Route

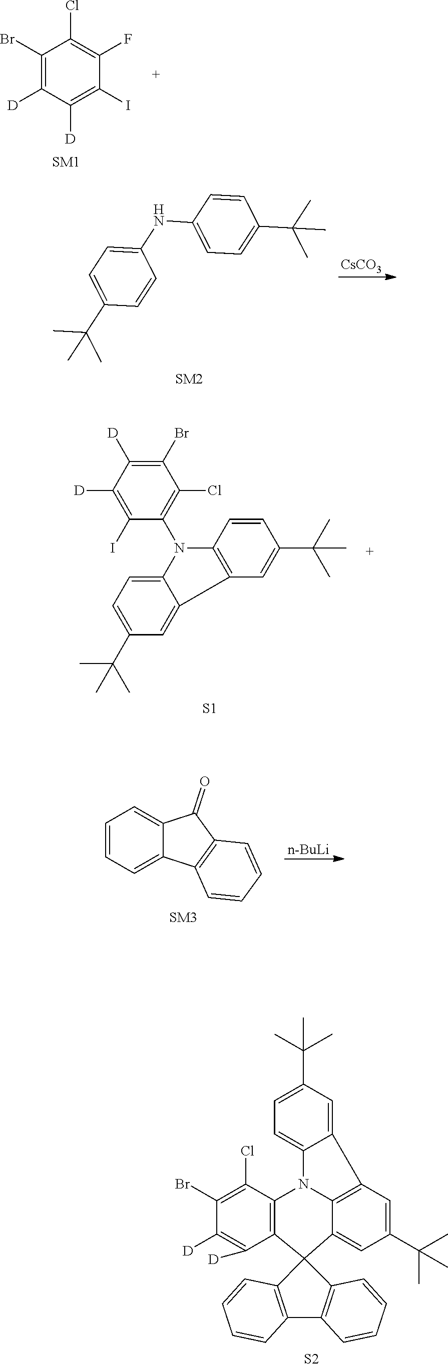

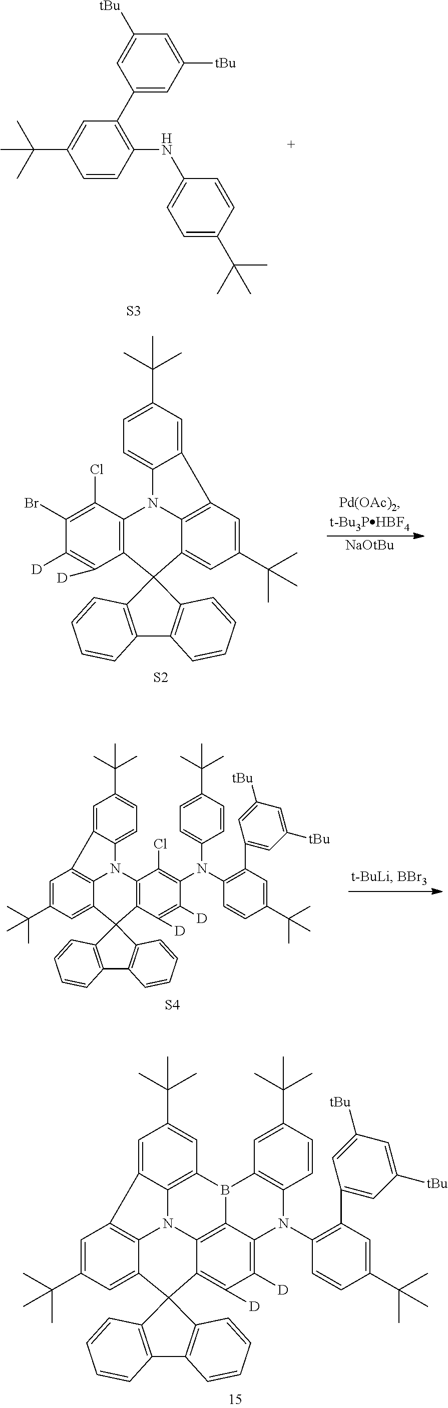

1) Compound SM1 (1 mmoL) and CsCO₃ (2 mmoL) are dissolved in 50 ml of anhydrous N,N-dimethylformamide (DMF), and then stirring is performed for 20 min; compound SM2 (1 mmoL) is added under nitrogen atmosphere to obtain a reaction system, and the reaction system is heated up to 120° C. for 15 h and then cooled to room temperature to obtain a reaction solution; a solvent (i.e., DMF) is removed from the reaction solution by means of rotary evaporation to obtain a residue; the residue is dissolved with 50 ml of dichloromethane, and then 50 ml of distilled water is added for a first extraction to obtain an organic phase; the residue after the first extraction is extracted with dichloromethane for three times to obtain an organic phase, 100 mL of dichloromethane being used for each extraction; the organic phases obtained from the four extractions are combined and then dried with anhydrous sodium sulfate; reduced pressure distillation is performed on the dried organic phase to remove a solvent (e.g., dichloromethane) therein so as to obtain a solid; and the solid is separated and purified by means of a silica gel chromatography column, an eluent used therein being a mixture of dichloromethane and petroleum ether, and a volume ratio of dichloromethane to petroleum ether being 1:4. Thus, an intermediate product S1 is obtained.
2) The intermediate product S1 (1 mmoL) is dissolved in 50 mL of tetrahydrofuran (THF), n-butyllithium (n-BuLi) (2 mmol, 2.7 M in n-hexane) at a low temperature (e.g., −78° C.) under nitrogen atmosphere, stirring is performed for dissolution, and then a solution of compound SM3 (1 mmol) in THF is slowly added to obtain a reaction solution; the reaction solution is stirred for reaction at room temperature for 12 h; after the reaction is completed, 0.5 mol/L HCl solution, H₂O and ethyl acetate (EA) are added for a first extraction so as to obtain an organic phase, then an aqueous phase after the first extraction is extracted with EA for several times (e.g., two times or three times) to obtain an organic phase, the organic phases obtained from the successive extractions are combined, washed with anhydrous DMF and then dried with sodium sulfate, and then rotary evaporation and column chromatography are performed to obtain an intermediate product S2.
3) Compound S3 (1 mmoL) and the intermediate product S2 (1 mmoL) are dissolved in 50 mL of toluene, and under nitrogen atmosphere, sodium tert-butoxide (NaOtBu) (2 mmoL), palladium acetate (0.05 mmoL) and tri-tert-butylphosphine tetrafluoroborate (t-Bu₃P·HBF₄) (0.5 mmoL) are added to obtain a reaction system; the reaction system is refluxed for 72 h, and then cooled to room temperature; a solvent (i.e., toluene) is removed from the reaction system by means of rotary evaporation to obtain a residue; the residue is dissolved with 50 ml of dichloromethane, and then 50 ml of distilled water is added for a first extraction to obtain an organic phase; the residue after the first extraction is extracted with dichloromethane for three times to obtain an organic phase, 100 mL of dichloromethane being used for each extraction; the organic phases obtained from the four extractions are combined and then dried with anhydrous sodium sulfate; and reduced pressure distillation is performed on the dried organic phase to remove a solvent (i.e., dichloromethane) therein so as to obtain a solid; and separation and purification is performed on the solid by means of a silica gel chromatography column, an eluent used therein being a mixture of dichloromethane and petroleum ether, and a volume ratio of dichloromethane to petroleum ether being 1:4. Thus, an intermediate product S4 is obtained.
4) The intermediate product S4 (1 mmoL) is dissolved in 60 mL of anhydrous tert-butylbenzene to obtain a reaction system; the reaction system is cooled to −78° C., and t-BuLi (1 mL, 2 mmoL, 2 M in hexane) is slowly added into the reaction system for reaction at 25° C. for 4 h, then, BBr₃ (247 mg, about 1 mmoL) is slowly added into the reaction system at −40° C.; then, the reaction system is heated up to room temperature, N,N-diisopropylethylamine (387 mg, 3 mmoL) is added into the reaction system, the reaction system is heated up to 80° C. for reaction for 12 h, and then cooled to room temperature, 5 mL of an aqueous sodium acetate solution (1 M) is added into the reaction system to quench the reaction; a solvent (i.e., tert-butylbenzene and water) is removed from the reaction system by means of rotary evaporation to obtain a residue; the residue is dissolved with 50 ml of dichloromethane, and then 50 ml of distilled water is added for a first extraction to obtain an organic phase; the residue after the first extraction is extracted with dichloromethane for three times to obtain an organic phase, 100 mL of dichloromethane being used for each extraction; the organic phases obtained from the four extractions are combined and then dried with anhydrous sodium sulfate; reduced pressure distillation is performed on the dried organic phase to remove a solvent (i.e., dichloromethane) therein so as to obtain a solid; and separation and purification is performed on the solid by means of a silica gel chromatography column, an eluent used therein being a mixture of dichloromethane and petroleum ether, and a volume ratio of dichloromethane to petroleum ether being 1:8. Thus, a target product, i.e., compound 15, is obtained.

Testing of Structure of Target Product, i.e., Compound 15: Through liquid chromatography-mass spectrometry (LC-MS) analysis, a following result of LC-MS (m/z) is obtained: a theoretical value being 994.63, and a tested value being 995.25.

### Embodiment 2: Synthesis of Compound 23

With reference to the synthesis steps and reaction conditions of Embodiment 1, compound 23 is synthesized. Through LC-MS analysis, a following result of LC-MS (m/z) is obtained: a theoretical value being 974.61, and a tested value being 975.23.

### Embodiment 3: Synthesis of Compound 46

With reference to the synthesis steps and reaction conditions of Embodiment 1, compound 46 is synthesized. Through LC-MS analysis, a following result of LC-MS (m/z) is obtained: a theoretical value being 1402.82, and a tested value being 1403.78.

### Embodiment 4: Synthesis of Compound 47

With reference to the synthesis steps and reaction conditions of Embodiment 1, compound 47 is synthesized. Through LC-MS analysis, a following result of LC-MS (m/z) is obtained: a theoretical value being 1222.73, and a tested value being 1223.51.

### Embodiment 5: Synthesis of Compound 55

With reference to the synthesis steps and reaction conditions of Embodiment 1, compound 55 is synthesized. Through LC-MS analysis, a following result of LC-MS (m/z) is obtained: a theoretical value being 1048.63, and a tested value being 1049.35.

### Embodiment 6: Synthesis of Compound 61

With reference to the synthesis steps and reaction conditions of Embodiment 1, compound 61 is synthesized. Through LC-MS analysis, a following result of LC-MS (m/z) is obtained: a theoretical value being 1142.66, and a tested value being 1143.40.

### Embodiment 7: Synthesis of Compound 65

With reference to the synthesis steps and reaction conditions of Embodiment 1, compound 65 is synthesized. Through LC-MS analysis, a following result of LC-MS (m/z) is obtained: a theoretical value being 1122.70, and a tested value being 1123.32.

### Embodiment 8: Synthesis of Compound 68

With reference to the synthesis steps and reaction conditions of Embodiment 1, compound 68 is synthesized. Through LC-MS analysis, a following result of LC-MS (m/z) is obtained: a theoretical value being 1280.75, and a tested value being 1281.67.

### Embodiment 9: Synthesis of Compound 69

With reference to the synthesis steps and reaction conditions of Embodiment 1, compound 69 is synthesized. Through LC-MS analysis, a following result of LC-MS (m/z) is obtained: a theoretical value being 1179.76, and a tested value being 1180.50.

### Embodiment 10: Synthesis of Compound 70

With reference to the synthesis steps and reaction conditions of Embodiment 1, compound 70 is synthesized. Through LC-MS analysis, a following result of LC-MS (m/z) is obtained: a theoretical value being 1248.69, and a tested value being 1249.57.

### Embodiment 11: Synthesis of Compound 72

With reference to the synthesis steps and reaction conditions of Embodiment 1, compound 72 is synthesized. Through LC-MS analysis, a following result of LC-MS (m/z) is obtained: a theoretical value being 1103.73, and a tested value being 1104.41.

### Embodiment 12: Synthesis of Compound 75

With reference to the synthesis steps and reaction conditions of Embodiment 1, compound 75 is synthesized. Through LC-MS analysis, a following result of LC-MS (m/z) is obtained: a theoretical value being 1202.76, and a tested value being 1203.50.

### Embodiment 13: Synthesis of Compound 77

With reference to the synthesis steps and reaction conditions of Embodiment 1, compound 77 is synthesized. Through LC-MS analysis, a following result of LC-MS (m/z) is obtained: a theoretical value being 966.60, and a tested value being 967.12.

### Embodiment 14: Synthesis of Compound 94

With reference to the synthesis steps and reaction conditions of Embodiment 1, compound 94 is synthesized. Through LC-MS analysis, a following result of LC-MS (m/z) is obtained: a theoretical value being 1076.66, and a tested value being 1077.38.

### Embodiment 15: Synthesis of Compound 97

Embodiment 1, compound 97 is synthesized. Through LC-MS analysis, a following result of LC-MS (m/z) is obtained: a theoretical value being 1134.71, and a tested value being 1135.47.

### Embodiment 16: Synthesis of Compound 98

With reference to the synthesis steps and reaction conditions of Embodiment 1, compound 98 is synthesized. Through LC-MS analysis, a following result of LC-MS (m/z) is obtained: a theoretical value being 1382.77, and a tested value being 1383.65.

### Embodiment 17: Synthesis of Compound 99

With reference to the synthesis steps and reaction conditions of Embodiment 1, compound 99 is synthesized. Through LC-MS analysis, a following result of LC-MS (m/z) is obtained: a theoretical value being 1183.69, and a tested value being 1184.41.

### Embodiment 18: Synthesis of Compound 103

With reference to the synthesis steps and reaction conditions of Embodiment 1, compound 103 is synthesized. Through LC-MS analysis, a following result of LC-MS (m/z) is obtained: a theoretical value being 1309.74, and a tested value being 1310.60.

### Embodiment 19: Synthesis of Compound 107

With reference to the synthesis steps and reaction conditions of Embodiment 1, compound 107 is synthesized. Through LC-MS analysis, a following result of LC-MS (m/z) is obtained: a theoretical value being 1164.56, and a tested value being 1165.28.

### Embodiment 20: Synthesis of Compound 108

With reference to the synthesis steps and reaction conditions of Embodiment 1, compound 108 is synthesized. Through LC-MS analysis, a following result of LC-MS (m/z) is obtained: a theoretical value being 1012.49, and a tested value being 1013.11.

### Embodiment 21: Synthesis of Compound 111

Embodiment 1, compound 111 is synthesized. Through LC-MS analysis, a following result of LC-MS (m/z) is obtained: a theoretical value being 1180.68, and a tested value being 1181.42.

### Embodiment 22: Synthesis of Compound 112

With reference to the synthesis steps and reaction conditions of Embodiment 1, compound 112 is synthesized. Through LC-MS analysis, a following result of LC-MS (m/z) is obtained: a theoretical value being 1460.99, and a tested value being 1461.97.

### Embodiment 23: Synthesis of Compound 116

With reference to the synthesis steps and reaction conditions of Embodiment 1, compound 116 is synthesized. Through LC-MS analysis, a following result of LC-MS (m/z) is obtained: a theoretical value being 1040.52, and a tested value being 1041.14.

### Embodiment 24: Synthesis of Compound 119

With reference to the synthesis steps and reaction conditions of Embodiment 1, compound 119 is synthesized. Through LC-MS analysis, a following result of LC-MS (m/z) is obtained: a theoretical value being 1188.74, and a tested value being 1189.26.

### Embodiment 25: Synthesis of Compound 120

With reference to the synthesis steps and reaction conditions of Embodiment 1, compound 120 is synthesized. Through LC-MS analysis, a following result of LC-MS (m/z) is obtained: a theoretical value being 1032.63, and a tested value being 1033.21.

### Embodiment 26: Synthesis of Compound 124

With reference to the synthesis steps and reaction conditions of Embodiment 1, compound 124 is synthesized. Through LC-MS analysis, a following result of LC-MS (m/z) is obtained: a theoretical value being 1014.51, and a tested value being 1015.11.

### Embodiment 27: Synthesis of Compound 127

Embodiment 1, compound 127 is synthesized. Through LC-MS analysis, a following result of LC-MS (m/z) is obtained: a theoretical value being 996.48, and a tested value being 997.02.

### Embodiment 28: Synthesis of Compound 128

With reference to the synthesis steps and reaction conditions of Embodiment 1, compound 128 is synthesized. Through LC-MS analysis, a following result of LC-MS (m/z) is obtained: a theoretical value being 1028.44, and a tested value being 1029.18.

### Embodiment 29: Synthesis of Compound 130

With reference to the synthesis steps and reaction conditions of Embodiment 1, compound 130 is synthesized. Through LC-MS analysis, a following result of LC-MS (m/z) is obtained: a theoretical value being 1007.55, and a tested value being 1008.13.

### Embodiment 30: Synthesis of Compound 131

With reference to the synthesis steps and reaction conditions of Embodiment 1, compound 131 is synthesized. Through LC-MS analysis, a following result of LC-MS (m/z) is obtained: a theoretical value being 1031.51, and a tested value being 1032.15.

### Embodiment 31: Synthesis of Compound 132

With reference to the synthesis steps and reaction conditions of Embodiment 1, compound 132 is synthesized. Through LC-MS analysis, a following result of LC-MS (m/z) is obtained: a theoretical value being 1023.52, and a tested value being 1024.16.

### Embodiment 32: Synthesis of Compound 133

With reference to the synthesis steps and reaction conditions of Embodiment 1, compound 133 is synthesized. Through LC-MS analysis, a following result of LC-MS (m/z) is obtained: a theoretical value being 1184.71, and a tested value being 1185.35.

### Embodiment 33: Synthesis of Compound 138

Embodiment 1, compound 138 is synthesized. Through LC-MS analysis, a following result of LC-MS (m/z) is obtained: a theoretical value being 1404.93, and a tested value being 1405.87.

### Embodiment 34: Synthesis of Compound 141

With reference to the synthesis steps and reaction conditions of Embodiment 1, compound 141 is synthesized. Through LC-MS analysis, a following result of LC-MS (m/z) is obtained: a theoretical value being 1436.88, and a tested value being 1438.00.

Several application examples in which the boron-nitrogen compounds of the embodiments of the present disclosure are applied in OLED devices are listed below, so as to further illustrate the beneficial effects of the compounds of the embodiments of the present disclosure. Materials used in the application examples are purchased commercially or synthesized in-house.

### Fabrication of OLED Devices

A reference fabrication method for device embodiments in the present disclosure is as follows: evaporating 50 nm to 500 nm of indium-tin-oxide (ITO)/Ag/ITO on an alkali-free glass substrate to serve as an anode; evaporating a hole injection layer (with a thickness of 5 nm to 20 nm), a hole transport layer (with a thickness of 50 nm to 120 nm), a light-emitting auxiliary layer (with a thickness of 5 nm to 120 nm), a light-emitting layer (with a thickness of 20 nm of 50 nm), a hole blocking layer (with a thickness of 5 nm to 20 nm), an electron transport layer (with a thickness of 20 nm to 80 nm) and an electron injection layer (with a thickness of 1 nm to 10 nm) on the anode; performing co-evaporation with Mg and Ag (with a weight ratio of 1:9, and a total thickness of 10 nm to 15 nm) to serve as a semi-transparent cathode; then, performing evaporation with a compound for a cover layer; and finally, encapsulating such a light-emitting device by using an epoxy resin adhesive under nitrogen atmosphere.

In some embodiments of the present disclosure, a method for fabricating the OLED devices is as follows: washing an alkali-free glass substrate with isopropyl alcohol for 15 min in an ultrasonic cleaning instrument, and performing ultraviolet (UV) ozone washing treatment on the alkali-free glass substrate for 30 min in air; evaporating ITO/Ag/ITO with a thickness of 100 nm on the treated substrate by using a vacuum vapor deposition method to serve as an anode; then, sequentially evaporating a hole injection layer (made of compound HT and compound PD, a weight percentage of compound PD being 2%, a total thickness being 10 nm), a hole transport layer (made of compound HT, a thickness being 130 nm), a light-emitting auxiliary layer (made of compound GP, a thickness being 50 nm), a green light-emitting layer (made of compound GHN01, compound GHP01, compound GD1 and compound 1, where compound GHN01 and compound GHP01 serve as a host material, and compound GD1 and compound 1 serve as a dopant material, and a weight ratio of compound GHN01, compound GHP01, compound GD1 and compound 1 is 66:30:3:1; and a total thickness of the green light-emitting layer being 30 nm), a hole blocking layer (made of compound HBL, a thickness being 5 nm), an electron transport layer (made of compound ET and compound Liq, where a weight ratio of compound ET and compound Liq is 1:1; a total thickness of the electron transport layer being 30 nm) and an electron injection layer (made of ytterbium (Yb), a thickness being 1 nm) in a stacked manner; then, performing co-evaporation with Mg and Ag (a weight ratio being 1:9, a total thickness being 13 nm) to serve as a semi-transparent cathode; then, evaporating compound CPL (a thickness being 65 nm) to serve as a cover layer; and finally, encapsulating such a light-emitting device by using an epoxy resin adhesive under nitrogen atmosphere. This example is referred to as Application Example 1. Molecular structural formulae of the relevant materials are as shown below (the following structures being only regarded as examples, and embodiments of the present disclosure being not limited thereto):

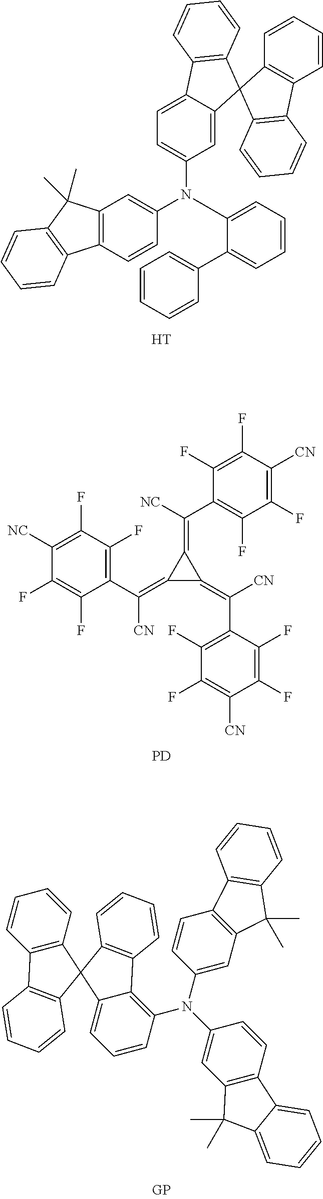

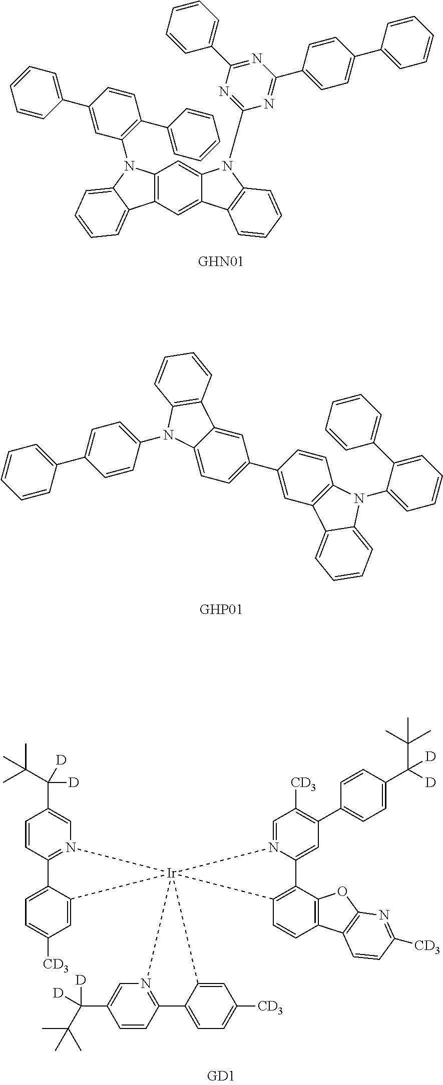

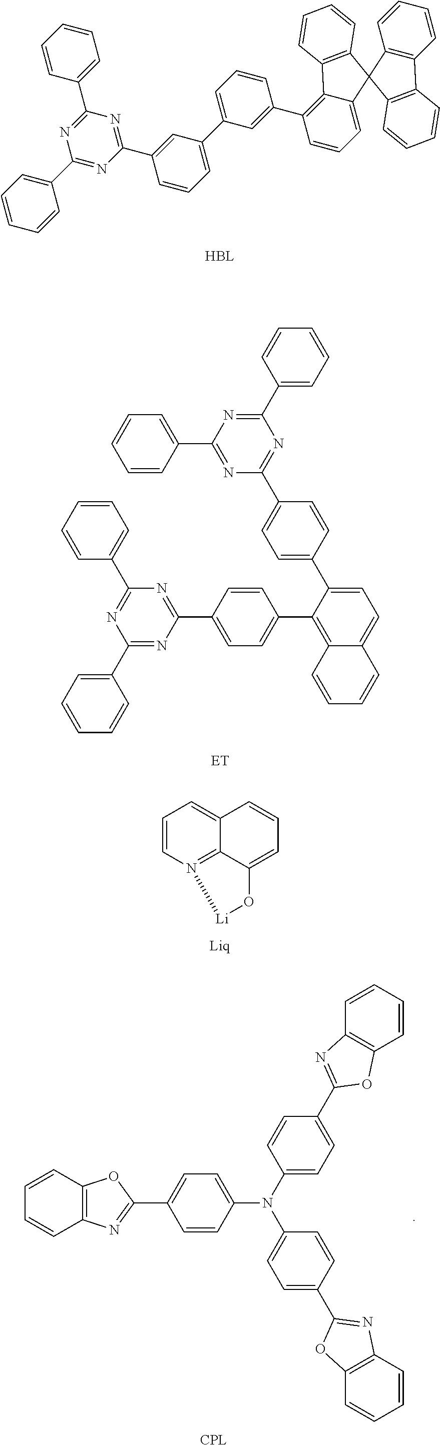

For the fabrication methods of OLED devices in Application Examples 2 to 34 and Comparison Examples 1 to 4, reference is made to the method for fabricating the OLED device in Application Example 1 above, differences lie in that compounds listed in Table 1 are substituted for compound 1 in Application Example 1 to serve as respective dopant materials. The dopant materials in Comparison Examples 1 to 4 are as follows:

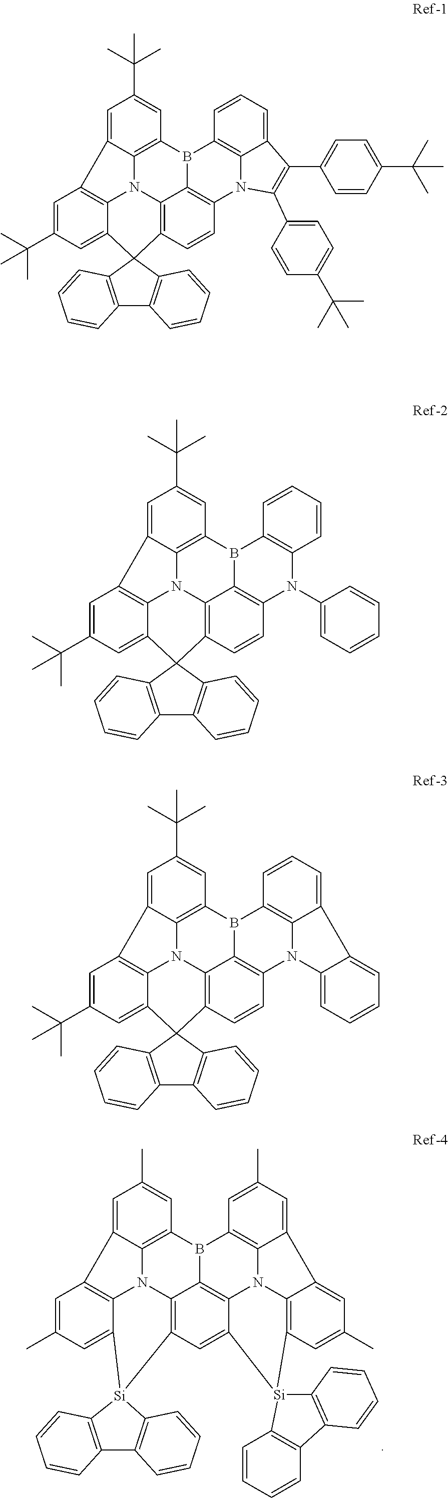

### Performance Evaluation of OLED Devices

Currents of each OLED device at different voltages are tested by means of a Keithley 2365 A digital nanovoltmeter, and then current densities of the OLED device at the different voltages are obtained by dividing the currents by an light-emitting area; brightnesses and radiation energy flux densities of the OLED device at the different voltages are tested by means of Konicaminolta CS-2000 spectroradiometer; according to the current densities and the brightnesses of the OLED device at the different voltages, an operation voltage Volt and a current efficiency at the same current density (10 mA/cm²) are obtained. BI is a current efficiency, and can be used as a parameter for measuring the light-emitting efficiency of green light. LT95 is a parameter for measuring a lifespan of an organic light-emitting material; and the larger the LTP5 is, the longer the lifespan of the organic light-emitting material is. Test data are as shown in Table 1, where the data are formed on the basis of data in Comparison Example 1.

TABLE 1
Organic electroluminescent devices
and electroluminescent properties

| Device | Dopant | | | |
|---|---|---|---|---|
| Example | Material | Volt | CE | LT95 |
| Application | Compound 15 | 99% | 115% | 120% |
| Example 1 | | | | |
| Application | Compound 23 | 101% | 117% | 110% |
| Example 2 | | | | |
| Application | Compound 46 | 101% | 120% | 116% |
| Example 3 | | | | |
| Application | Compound 47 | 100% | 121% | 123% |
| Example 4 | | | | |
| Application | Compound 55 | 99% | 119% | 110% |
| Example 5 | | | | |
| Application | Compound 61 | 100% | 122% | 122% |
| Example 6 | | | | |
| Application | Compound 65 | 99% | 123% | 127% |
| Example 7 | | | | |
| Application | Compound 68 | 100% | 124% | 112% |
| Example 8 | | | | |
| Application | Compound 69 | 99% | 124% | 129% |
| Example 9 | | | | |
| Application | Compound 70 | 100% | 122% | 119% |
| Example 10 | | | | |
| Application | Compound 72 | 100% | 123% | 120% |
| Example 11 | | | | |
| Application | Compound 75 | 100% | 122% | 119% |
| Example 12 | | | | |
| Application | Compound 77 | 100% | 116% | 110% |
| Example 13 | | | | |
| Application | Compound 94 | 99% | 121% | 110% |
| Example 14 | | | | |
| Application | Compound 97 | 100% | 123% | 113% |
| Example 15 | | | | |
| Application | Compound 98 | 99% | 123% | 120% |
| Example 16 | | | | |
| Application | Compound 99 | 100% | 120% | 125% |
| Example 17 | | | | |
| Application | Compound | 99% | 122% | 130% |
| Example 18 | 103 | | | |
| Application | Compound | 101% | 120% | 133% |
| Example 19 | 107 | | | |
| Application | Compound | 101% | 124% | 115% |
| Example 20 | 108 | | | |
| Application | Compound | 100% | 127% | 131% |
| Example 21 | 111 | | | |
| Application | Compound | 100% | 128% | 135% |
| Example 22 | 112 | | | |
| Application | Compound | 99% | 125% | 140% |
| Example 23 | 116 | | | |
| Application | Compound | 99% | 131% | 139% |
| Example 24 | 119 | | | |
| Application | Compound | 99% | 128% | 134% |
| Example 25 | 120 | | | |
| Application | Compound | 99% | 130% | 138% |
| Example 26 | 124 | | | |
| Application | Compound | 100% | 124% | 123% |
| Example 27 | 127 | | | |
| Application | Compound | 100% | 127% | 119% |
| Example 28 | 128 | | | |
| Application | Compound | 99% | 125% | 120% |
| Example 29 | 130 | | | |
| Application | Compound | 101% | 123% | 128% |
| Example 30 | 131 | | | |
| Application | Compound | 101% | 125% | 114% |
| Example 31 | 132 | | | |
| Application | Compound | 99% | 129% | 131% |
| Example 32 | 133 | | | |
| Application | Compound | 100% | 130% | 133% |
| Example 33 | 138 | | | |
| Application | Compound | 100% | 128% | 120% |
| Example 34 | 141 | | | |
| Comparison | Ref-1 | 100% | 100% | 100% |
| Example 1 | | | | |
| Comparison | Ref-2 | 101% | 102% | 95% |
| Example 2 | | | | |
| Comparison | Ref-3 | 100% | 105% | 98% |
| Example 3 | | | | |
| Comparison | Ref-4 | 102% | 107% | 102% |
| Example 4 | | | | |

As can be seen from Table 1, compared with the OLED devices in Comparison Examples 1 to 4, the OLED devices in Application Examples 1 to 34 have comparable operating voltages, higher BI light-emitting efficiencies and longer lifespans. As can be seen from Application Examples 1 and 2, in a case where Y₁ represents absence, and Y₃ represents presence, the compounds in embodiments of the present disclosure perform better in the OLED devices by means of substitution transformation of R₁, R₂, R₃ and R₄ on a boron-nitrogen parent nucleus. As can be seen from Application Examples 3 to 34, by means of symmetrical fused structures on upper sides of a boron-nitrogen parent nucleus together with the selected R₁, R₂, R₃, R₄, R₅ and rings M1, M2, M3 and M4, the application properties, especially, the light-emitting efficiency, of the compounds in the embodiments of the present disclosure can be further improved. The improved properties of the application examples are based on that, the combinations of different multi-membered fused heterocyclic structures with limiting groups such as a tert-butyl group and a cycloalkyl group enable boron-nitrogen compound materials to have better light-emitting efficiency. In addition, the dopant materials have a good compatibility, which enables a light-emitting layer to achieve a better balance between electron transport and hole transport and a better exciton conversion yield, significantly reduces the power consumption of a device and improves the service lifespan.

These specific embodiments are only explanations of the present disclosure, but not limitations of the present disclosure. Those skilled in the art may make modifications, without creative contribution, to these embodiments according to needs after reading this description, but those modifications shall be included in the scope, which are protected by the patent law, of the claims of the present disclosure.

1. (canceled)

2. (canceled)

3. (canceled)

4. (canceled)

5. (canceled)

6. (canceled)

7. (canceled)

8. (canceled)

9. (canceled)

10. A boron-nitrogen compound with a multi-membered fused ring, wherein the structure of the boron-nitrogen compound with the multi-membered fused ring is any one selected from following chemical structures: 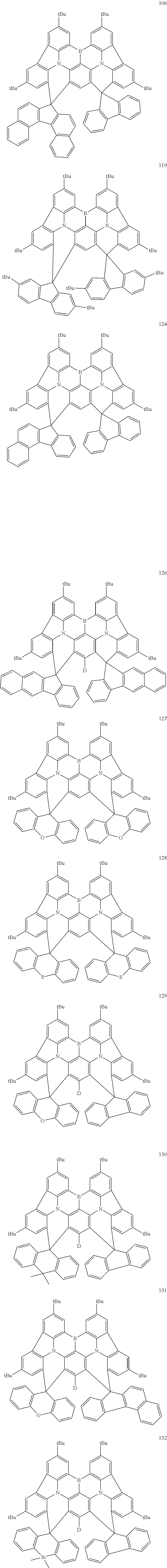
wherein tBu represents a tert-butyl group, and Ph represents a phenyl group.

11. An organic electroluminescent device, comprising:
a substrate;
a first electrode, disposed on the substrate;
an organic light-emitting functional layer, disposed on the first electrode; and
a second electrode, disposed on the organic light-emitting functional layer, wherein
the organic light-emitting functional layer comprises a light-emitting layer; and the light-emitting layer comprises the boron-nitrogen compound with the multi-membered fused ring according to claim 10.

12. A composition, containing the boron-nitrogen compound with the multi-membered fused ring according to claim 10.

13. A preparation, containing:
the boron-nitrogen compound with the multi-membered fused ring according to claim 10, and
at least one solvent.

14. A preparation, containing:
the composition according to claim 12, and
at least one solvent.

15. A display apparatus, comprising the organic electroluminescent device according to claim 11.

16. A lighting apparatus, comprising the organic electroluminescent device according to claim 11.
